(19) United States
(12) Patent Application Publication
(10) Pub. No.: US 2026/0359184 A1
(43) Pub. Date: Nov. 12, 2026

(54) WORKLOAD REPORT GENERATOR FOR WORKLOADS IN A COMPUTING ENVIRONMENT

(71) Applicant: Dell Products L.P., Round Rock, TX (US)

(72) Inventors: Richard Andrew Crisp, Austin, TX (US); John Christian Pflueger, Jonestown, TX (US); Alyson Channing Freeman, Round Rock, TX (US); Owen Glynn Griffiths, Dublin (IE)

(21) Appl. No.: 19/204,592

(22) Filed: May 11, 2025

(51) Int. Cl. G06F 11/30; G06F 9/48; G06F 30/20

(52) U.S. Cl. CPC G06F 11/3051; G06F 9/4881; G06F 30/20

(57) ABSTRACT

A method for managing an information handling system (IHS) includes initiating, by a workload orchestration system, execution of a workload in the IHS, wherein the workload is executed using a set of computing components of the IHS, after initiating the workload, monitoring each computing component of the set of computing components executing the workload to obtain computing component information of each computing component in the set of computing components, computing resource utilization of the set of computing components, and grid emission information, storing, in a digital twin creation tool, a digital twin of the workload based on the computing component information, the computing resource utilization, and the power grid emission intensity information, and using the workload digital twin for evaluation of the workload after completion of the workload.

### BACKGROUND

Computing environments execute any number of workloads using one or more computing components that include hardware. Monitoring the computing resource usage of workloads may be performed at the computing environment level. Further, the power consumption and energy usage may be measured at the computing environment level. Calculating the energy consumption at the component or workload level may enable an administrator of the computing environment to manage each component to reduce, for example, the carbon footprint of the workloads and/or computing components.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1.1 shows/illustrates a diagram of a system in accordance with one or more embodiments disclosed herein.

FIG. 1.2 shows a diagram of an IHS in accordance with one or more embodiments disclosed herein.

FIG. 1.3 shows a diagram of a digital twin (DT) module in accordance with one or more embodiments disclosed herein.

FIG. 1.4 shows a diagram of one or more DT creation templates.

FIG. 1.5 shows a diagram of an example DT.

FIGS. 2.1-2.2 show a method for managing a workload in accordance with one or more embodiments disclosed herein.

FIG. 3.1 shows a flowchart of a method for a second life evaluation of hardware during operation in accordance with one or more embodiments of the invention.

FIG. 3.2 shows a flowchart of a method for a second life evaluation of decommissioned hardware in accordance with one or more embodiments of the invention.

FIG. 4 shows a flowchart of a method for managing usage of an information handling system digital twin in accordance with one or more embodiments of the invention.

FIG. 5 shows a diagram of a computing device in accordance with one or more embodiments of the invention.

### DETAILED DESCRIPTION

Specific embodiments will now be described with reference to the accompanying figures. In the following description, numerous details are set forth as examples of the invention. It will be understood by those skilled in the art that one or more embodiments of the present invention may be practiced without these specific details, and that numerous variations or modifications may be possible without departing from the scope of the invention. Certain details known to those of ordinary skill in the art are omitted to avoid obscuring the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

Throughout this disclosure, elements of figures may be labeled as A to N, A to P, A to M, or A to L. As used herein, the aforementioned labeling means that the element may include any number of items, and does not require that the element include the same number of elements as any other item labeled as A to N, A to P, A to M, or A to L. For example, a data structure may include a first element labeled as A and a second element labeled as N. This labeling convention means that the data structure may include any number of the elements. A second data structure, also labeled as A to N, may also include any number of elements. The number of elements of the first data structure and the number of elements of the second data structure may be the same or different.

As used herein, the phrase operatively connected, operably connected, or operative connection, means that there exists between elements, components, and/or devices a direct or indirect connection that allows the elements to interact with one another in some way. For example, the phrase ‘operably connected’ may refer to any direct (e.g., wired directly between two devices or components) or indirect (e.g., wired and/or wireless connections between any number of devices or components connecting the operably connected devices) connection. Thus, any path through which information may travel may be considered an operable connection.

Embodiments of the invention include systems and methods for managing workloads executing in one or more information handling systems. Specifically, embodiments of the invention include methods and systems for generating workload digital twins for scheduled workloads. Embodiments of the invention enable the tracking and monitoring of workload information to generate a workload characterization entry (also referred to as a “workload report”) that stores computing component information of the servers and/or other hardware used to execute the workload, computing resource utilization, and power grid emission information. The collective information stored for the workload characterization entry may include, for example, the nodes involved for the workload, the component resource utilization such as processing, storage, memory, and networking, a timeframe for the workload, grid emission intensity caused by execution of the workload, compute intensity data tracked in real-time to the execution of the workload, and service information for services external to the computing environment (also referred to as an information handling system (IHS)) used for the workload execution.

Embodiments of the invention further includes functionality for managing the hardware of the computing components. For example, embodiments of the invention include functionality for performing a second life evaluation of computing components that utilize hardware. The second life evaluations may be used to identify hardware components that would benefit from a replacement and/or upgrade. Embodiments of the invention include monitoring operations of the computing components based on the execution of workloads. Based on the monitoring, embodiments of the invention may further include the facilitation of second life opportunities of detected hardware that would benefit based on performance metrics. The facilitation may include, for example, initiating a re-deployment of the hardware to a second computing environment, and initiating an end of life disassembly of a computing component to decommission at least a portion of the hardware components comprising the computing component and, if relevant, repurposing a second portion of the hardware components.

Embodiments of the invention further include using persistent digital twins of computing components, hardware components, workloads, and/or computing environments such as data centers for the analysis of such entities. Embodiments of the invention include creating, utilizing, and preserving a library of one or more digital twins to enhance the configuration, modeling, and optimization of computing environments. The digital twins may be used to serve as independent entities used for various solutions such as component analysis (e.g., for second life evaluations discussed herein), for component replacement in workloads, and/or for predictive analysis. The persistent digital twins may serve other solutions without departing from the invention.

Various embodiments of the invention are described below.

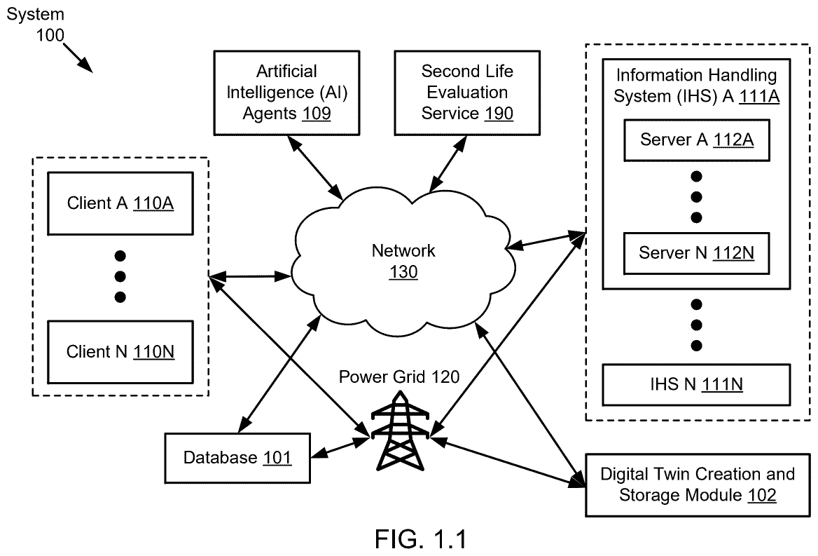

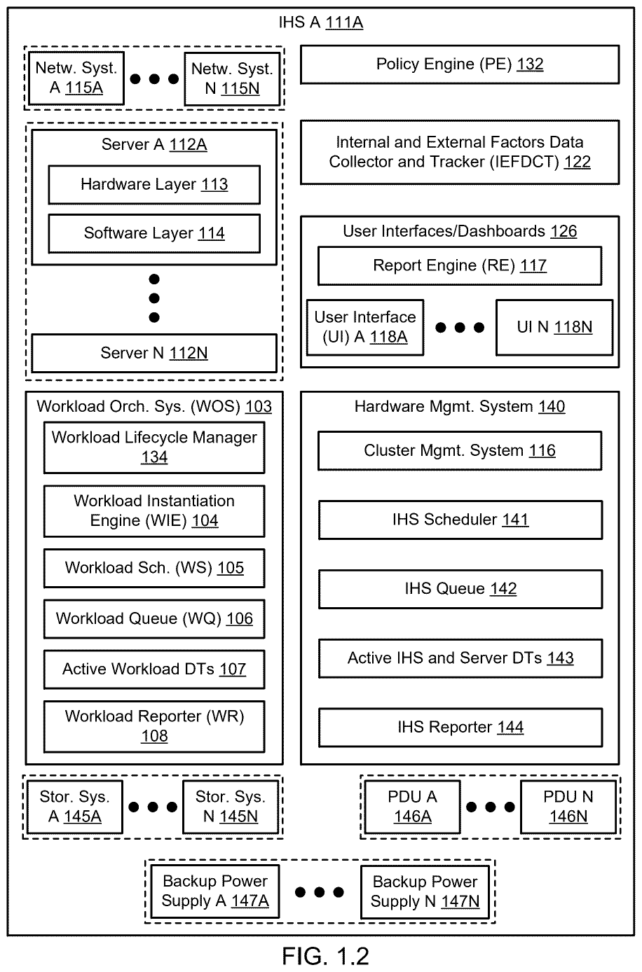

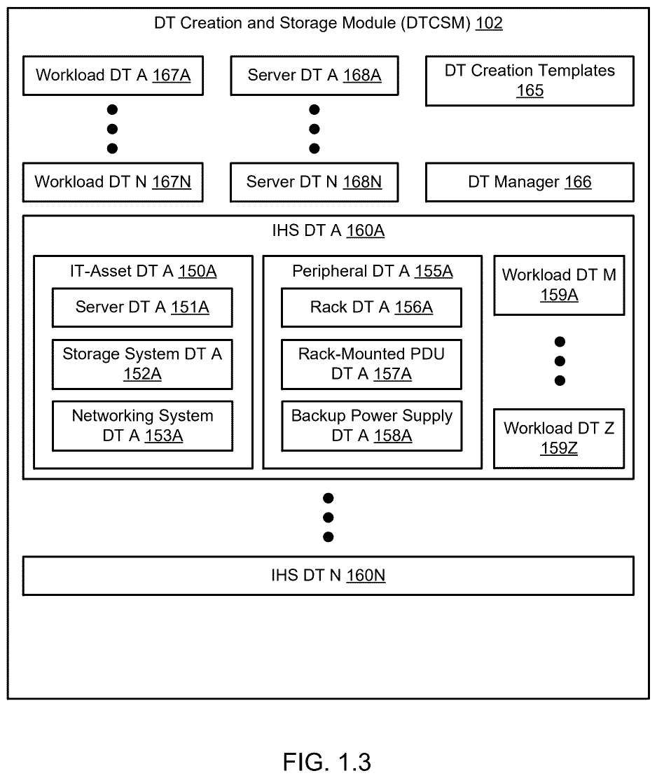

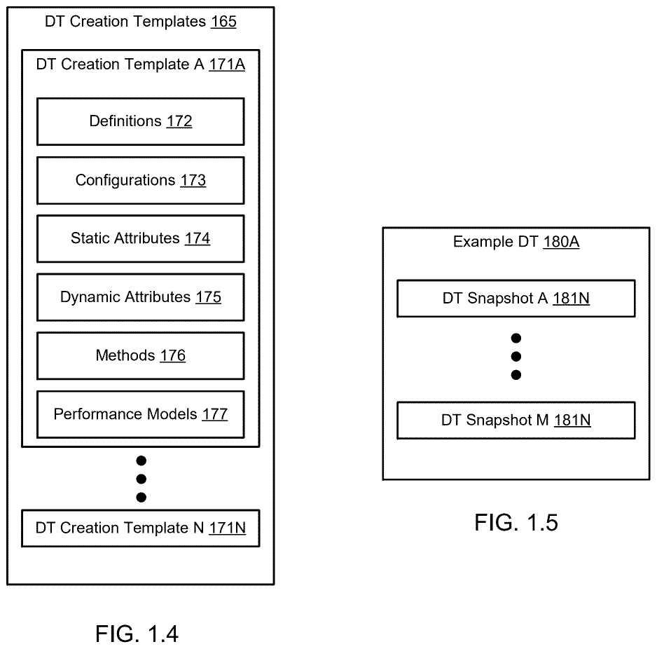

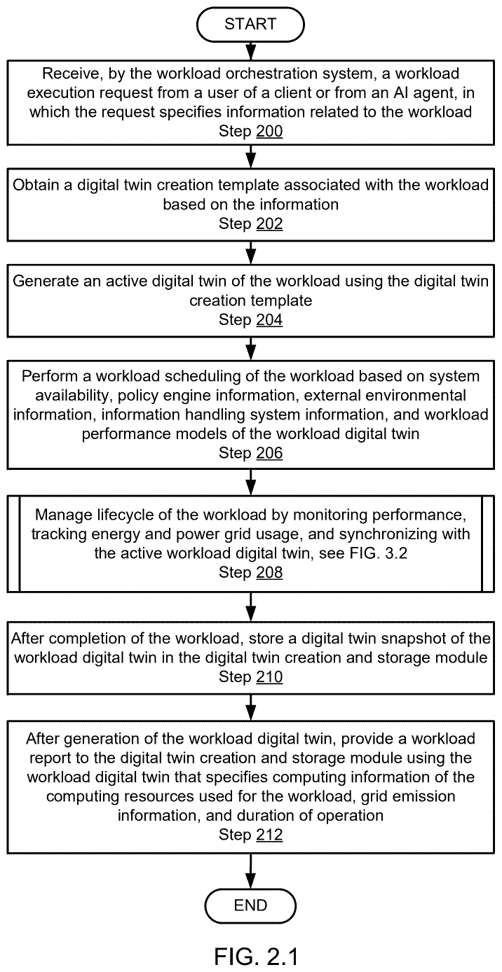

FIG. 1.1 shows a diagram of a system (100) in accordance with one or more embodiments disclosed herein. The system (100) includes any number of clients (e.g., Client A (110A), Client N (110N), etc.), a database (101), any number of IHSs (e.g., IHS A (111A), IHS N (111N), etc.), a network (130), any number of power grids (e.g., 120), a digital twin creation and storage module (102), any number of artificial intelligence (AI) agents (109), and a second life evaluation service (190). The system (100) may include additional, fewer, and/or different components without departing from the scope of the embodiments disclosed herein. Each component may be operably/operatively connected to any of the other components via any combination of wired and/or wireless connections. Each component illustrated in FIG. 1.1 is discussed below.

In one or more embodiments, the clients (e.g., 110A, 110N, etc.), the database (101), the IHSs (e.g., 111A, 111N, etc.), the network (130), the power grids (e.g., 120), the AI agents (109), the second life evaluation service (190), and the digital twin creation and storage module (102) may be (or may include) physical hardware or logical devices, as discussed below. While FIG. 1.1 shows a specific configuration of the system (100), other configurations may be used without departing from the scope of the embodiments disclosed herein. For example, although the clients (e.g., 110A, 110N, etc.) and the IHSs (e.g., 111A, 111N, etc.) are shown to be operatively connected through a communication network (e.g., 130), the clients (e.g., 110A, 110N, etc.) and the IHSs (e.g., 111A, 111N, etc.) may be directly connected (e.g., without an intervening communication network).

As yet another example, although (i) the clients (e.g., 110A, 110N, etc.) and an IHS (not shown) can be considered as deployed to a “functional edge region” of the system (100) (as edge devices), (ii) the IHSs (e.g., 111A, 111N, etc.) can be considered as deployed to a “far edge region” of the system (100) (as edge nodes), and (iii) the digital twin creation and storage module (125) and the database (101) can be considered as deployed to a “near edge region” of the system (100), the system (100) may include another region (e.g., another logical layer) in between the far edge region and the near edge region.

As yet another example, in one embodiment, a functional edge region (where the actual functioning happens such as, for example, a user uses a client to make a product or to deliver a service), a far edge region (including, at least, compute, storage, and/or network access devices focused on data acquisition and processing), and a near edge region of the system (100) may be co-located in one site/factory, and, in another embodiment, the functional edge and far edge regions may be co-located in one site and the near edge region may represent a “cloud” environment (or a cloud computing environment). In this example, the near edge region may be far away from the functional edge and far edge regions, where the near edge region may represent a centralized and geographically distant cloud environment (e.g., an environment that is hundreds of miles away from the site). Further, in this example, the database (101) and the digital twin creation and storage module (102) may be some of the cloud devices that execute on the cloud environment.

Further, in the aforementioned example, even though the functional edge and far edge regions are described as co-located in one site and the near edge region is described as representing a cloud environment, the system (100) may include another region/layer (e.g., a fog layer) in between the far edge region and near edge region. In one or more embodiments, the fog layer may include one or more “fog” devices, similar to IHS A (111A), in which both the fog devices and IHS A (11A) perform distributed computing and focus on the physical deployment of compute and storage resources in relation to data that is being produced (e.g., the difference is a matter of where those resources are located such as edge computing refers to computational processes being done at or near the “edge” of an Internet of Things (IoT) network, whereas fog computing refers to the network connections between an edge node (e.g., 111N) and a cloud device (e.g., 105) to extend the cloud device closer to the edge of the IoT network).

In one or more embodiments, each component (e.g., 110A, 105, 125, 120, 111A, etc.) of the system (100) may be part of a business operation region (BOR) (not shown) of an organization, in which the BOR corresponds to a geographic region (e.g., a zone, a city, a county, a state, a province, a country, a country grouping (e.g., the European Union), etc.). For example, IHS A (111A) of Organization X may be located in Austin, Texas and IHS N (111N) of Organization X may be located in the Netherlands, in which Organization X has multiple geographically distributed IHSs (e.g., edge nodes) around the world.

In one or more embodiments, in one architecture (e.g., the “unidirectional” architecture), one of the edge nodes (e.g., the parent edge node) of an organization may be deployed to the United States, which serves (e.g., shares) data to/among the remaining edge nodes (e.g., the child edge nodes that are deployed to Argentina, India, and France) of the organization. In this architecture, the child edge nodes may transmit their data to the parent edge node so that the parent edge node stays updated. Thereafter, the parent edge node may distribute/forward received data to the child edge nodes to keep the child edge nodes equally updated.

In another architecture (e.g., the “bidirectional” architecture), one of the edge nodes of an organization may be deployed to Greece and the other one may be deployed to Spain, in which both edge nodes know each other and when a data change is occurred in one of them, the other edge node may automatically obtain that data to stay updated.

In another architecture (e.g., the “multidirectional” architecture), an organization may have multiple edge nodes deployed around the world and all the edge nodes know each other. When one of the edge nodes is updated (e.g., when that edge node receives a software package), the remaining edge nodes are updated accordingly (e.g., by sending a data transfer request to each of the remaining edge nodes).

In one or more embodiments, the functioning of the clients (e.g., 110A, 110N, etc.) and the IHSs (e.g., 111A, 111N, etc.) is not dependent upon the functioning and/or existence of the other components (e.g., devices) in the system (100). Rather, the clients and the IHSs may function independently and perform operations locally that do not require communication with other components. Accordingly, embodiments disclosed herein should not be limited to the configuration of components shown in FIG. 1.1.

As used herein, “communication” may refer to simple data passing, or may refer to two or more components coordinating a job. As used herein, the term “data” is intended to be broad in scope. In this manner, that term embraces, for example (but not limited to): a data stream (or stream data), data chunks, data blocks, atomic data, emails, objects of any type, files of any type (e.g., media files, spreadsheet files, database files, etc.), contacts, directories, sub-directories, volumes, etc.

As used herein, a “volume” may be analogous to a logical unit number in a storage area network (SAN), in which a volume may be a subset of the database's (105) capacity presented by a node of the database as a local block device. A volume's data may be evenly distributed across all storage resources of the database (101), for example, according to a data layout selected for the database (101).

In one or more embodiments, although terms such as “document”, “file”, “segment”, “block”, or “object” may be used by way of example, the principles of the present disclosure are not limited to any particular form of representing and storing data or other information. Rather, such principles are equally applicable to any object capable of representing information.

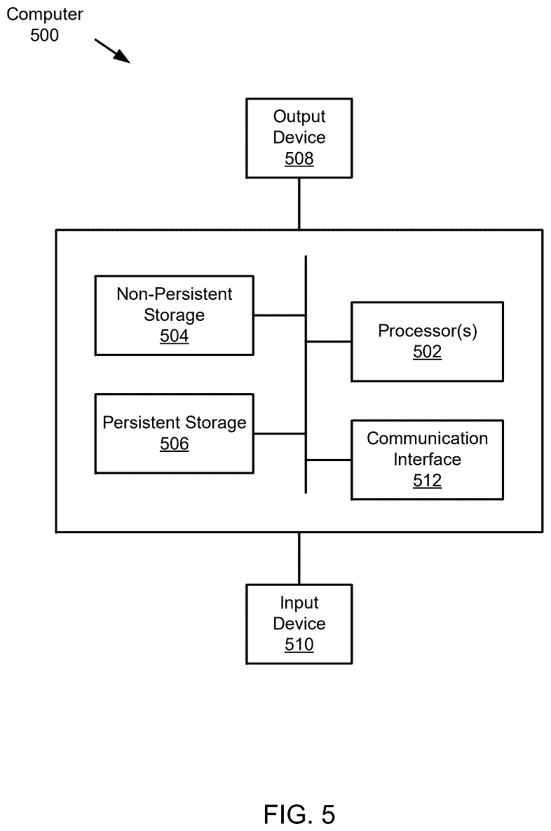

In one or more embodiments, the system (100) may be a distributed system (e.g., a data processing environment) and may deliver at least computing power (e.g., real-time (on the order of milliseconds (ms) or less) network monitoring, server virtualization, data deduplication, etc.), storage capacity (e.g., data backup), and data protection (e.g., software-defined data protection, disaster recovery, etc.) as a service to users (e.g., people, tenants, etc.) of clients (e.g., 110A, 110N, etc.). For example, the system (100) may be configured to organize unbounded, continuously generated data into a data stream. The system (100) may also represent a comprehensive middleware layer executing on computing devices (e.g., 500, FIG. 5) that supports application and storage environments.

In one or more embodiments, the system (100) may support one or more virtual machine (VM) environments, and may map capacity requirements (e.g., computational load, storage access, etc.) of VMs and supported applications to available resources (e.g., processing resources, storage resources, etc.) managed by the environments. Further, the system (100) may be configured for workload placement collaboration and computing resource (e.g., processing, storage/memory, virtualization, networking, etc.) exchange.

To provide computer-implemented services to the users, the system (100) may perform some computations (e.g., data collection, distributed processing of collected data, etc.) locally (e.g., at the users' site using the clients (e.g., 110A, 110N, etc.)) and other computations remotely (e.g., away from the users' site using the IHSs (e.g., 111A, 111N, etc.)) from the users. By doing so, the users may utilize different computing devices (e.g., 500, FIG. 5) that have different quantities of computing resources (e.g., processing cycles, memory, storage, etc.) while still being afforded consistent user experience. For example, by performing some computations remotely, the system (100) (i) may maintain the consistent user experience provided by different computing devices even when the different computing devices possess different quantities of computing resources, and (ii) may process data more efficiently in a distributed manner by avoiding the overhead associated with data distribution and/or command and control via separate connections.

As used herein, “computing” refers to any operations that may be performed by a computer, including (but not limited to): computation, data storage, data retrieval, communications, etc. Further, as used herein, a “computing device” refers to any device in which a computing operation may be carried out. A computing device may be, for example (but not limited to): a compute component, a storage component, a network device, a telecommunications component, etc.

As used herein, a “resource” refers to any program, application, document, file, asset, executable program file, desktop environment, computing environment, or other resource made available to, for example, a user/customer of a client (described below). The resource may be delivered to the client via, for example (but not limited to): conventional installation, a method for streaming, a VM executing on a remote computing device, execution from a removable storage device connected to the client (such as universal serial bus (USB) device), etc.

In one or more embodiments, a client (e.g., 110A, 110N, etc.) may include functionality to, e.g.: (i) capture sensory input (e.g., sensor data) in the form of text, audio, video, touch or motion, (ii) collect massive amounts of data at the edge of an IoT network (where, the collected data may be grouped as: (a) data that needs no further action and does not need to be stored, (b) data that should be retained for later analysis and/or record keeping, and (c) data that requires an immediate action/response), (iii) provide to other entities (e.g., IHS A (111A), the database (101), etc.), store, or otherwise utilize captured sensor data (and/or any other type and/or quantity of data), (iv) provide surveillance services (e.g., determining object-level information, performing face recognition, etc.) for scenes (e.g., a physical region of space), (v) initiate AI/ML model training and/or AI inferencing applications on one or more IHSs (e.g., 111A, 111N, etc.), (vi) monitor the status of the AI model training and/or receive the results of AI inferencing applications, and/or (vii) be used by any number of users for initiating and executing workloads. One of ordinary skill will appreciate that the client may perform other functionalities without departing from the scope of the embodiments disclosed herein.

In one or more embodiments, the clients (e.g., 110A, 110N, etc.) may be geographically distributed devices (e.g., user devices, front-end devices, etc.) and may have relatively restricted hardware and/or software resources when compared to the IHSs (e.g., 111A, 111N, etc.). As being, for example, a sensing device, each of the clients may be adapted to provide monitoring services. For example, a client may monitor the state of a scene (e.g., objects disposed in a scene). The monitoring may be performed by obtaining sensor data from sensors that are adapted to obtain information regarding the scene, in which a client may include and/or be operatively coupled to one or more sensors (e.g., a physical device adapted to obtain information regarding one or more scenes).

In one or more embodiments, the sensor data may be any quantity and types of measurements (e.g., of a scene's properties, of an environment's properties, etc.) over any period(s) of time and/or at any points-in-time (e.g., any type of information obtained from one or more sensors, in which different portions of the sensor data may be associated with different periods of time (when the corresponding portions of sensor data were obtained)). The sensor data may be obtained using one or more sensors. The sensor may be, for example (but not limited to): a visual sensor (e.g., a camera adapted to obtain optical information (e.g., a pattern of light scattered off of the scene) regarding a scene/environment), an audio sensor (e.g., a microphone adapted to obtain auditory information (e.g., a pattern of sound from the scene) regarding a scene), an electromagnetic radiation sensor (e.g., an infrared sensor), a chemical detection sensor, a temperature sensor, a humidity sensor, a count sensor, a distance sensor, a global positioning system sensor, a biological sensor, a differential pressure sensor, a corrosion sensor, etc.

In one or more embodiments, the clients (e.g., 110A, 110N, etc.) may be physical or logical computing devices configured for hosting one or more workloads, or for providing a computing environment whereon workloads may be implemented. The clients may provide computing environments that are configured for, at least: (i) workload placement collaboration, (ii) computing resource (e.g., processing, storage/memory, virtualization, networking, etc.) exchange, and (iii) protecting workloads (including their applications and application data) of any size and scale (based on, for example, one or more service level agreements (SLAs) configured by users of the clients). The clients (e.g., 110A, 110N, etc.) may correspond to computing devices that one or more users use to interact with one or more components of the system (100).

In one or more embodiments, a client (e.g., 110A, 110N, etc.) may represent a physical appliance or a computing device operated by one or more individuals of (or employed by) an organization. Examples of said individual(s) may include, but not limited to, any organization executive(s) (e.g., chief executive officer (CEO), chief financial officer (CFO), etc.), and any employee(s) in the accounting/finance team of the organization (e.g., a collector person). Further, the organization may refer to any enterprise at least engaged in for-profit commercial, industrial, or professional activities.

In one or more embodiments, a client (e.g., 110A, 110N, etc.) may include any number of applications (and/or content accessible through the applications) that provide computer-implemented services to a user. Applications may be designed and configured to perform one or more functions instantiated by a user of the client. In order to provide application services, each application may host similar or different components. The components may be, for example (but not limited to): instances of databases, instances of email servers, etc. Applications may be executed on one or more clients as instances of the application.

Applications may vary in different embodiments, but in certain embodiments, applications may be custom developed or commercial (e.g., off-the-shelf) applications that a user desires to execute in a client (e.g., 110A, 110N, etc.). In one or more embodiments, applications may be logical entities executed using computing resources of a client. For example, applications may be implemented as computer instructions stored on persistent storage of the client that when executed by the processor(s) of the client, cause the client to provide the functionality of the applications described throughout the application.

In one or more embodiments, while performing, for example, one or more operations requested by a user, applications installed on a client (e.g., 110A, 110N, etc.) may include functionality to request and use physical and logical resources of the client. Applications may also include functionality to use data stored in storage/memory resources of the client. The applications may perform other types of functionalities not listed above without departing from the scope of the embodiments disclosed herein. While providing application services to a user, applications may store data that may be relevant to the user in storage/memory resources of the client.

In one or more embodiments, to provide services to the users, the clients (e.g., 110A, 110N, etc.) may utilize, rely on, or otherwise cooperate with the IHSs (e.g., 111A, 111N, etc.) and/or the database (101). For example, the clients may issue requests to IHS A (111A) to receive responses and interact with various components of IHS A (111A). The clients may also request data from and/or send data to IHS A (111A) (for example, the clients may transmit information to IHS A that allows IHS A to perform computations, the results of which are used by the clients to provide services to the users). As yet another example, the clients may utilize computer-implemented services provided by IHS N (111N). When the clients interact with IHS N (111N), data that is relevant to the clients may be stored (temporarily or permanently) in IHS N (111N).

In one or more embodiments, a client (e.g., 110A, 110N, etc.) may be capable of, e.g.: (i) collecting users' inputs, (ii) correlating collected users' inputs to the computer-implemented services to be provided to the users, (iii) communicating with the IHSs (e.g., 111A, 111N, etc.) and/or the database (101) that perform computations necessary to provide the computer-implemented services, (iv) using the computations performed by, for example, IHS A (111A) to provide the computer-implemented services in a manner that appears (to the users) to be performed locally to the users, and/or (v) communicating with any virtual desktop (VD) in a virtual desktop infrastructure (VDI) environment (or a virtualized architecture) provided by the servers (using any known protocol in the art), for example, to exchange remote desktop traffic or any other regular protocol traffic (so that, once authenticated, users may remotely access independent VDs).

As described above, the clients (e.g., 110A, 110N, etc.) may provide computer-implemented services to users (and/or other computing devices). The clients may provide any number and any type of computer-implemented services. To provide computer-implemented services, each client may include a collection of physical components (e.g., processing resources, storage/memory resources, networking resources, etc.) configured to perform operations of the client and/or otherwise execute a collection of logical components (e.g., virtualization resources) of the client.

In one or more embodiments, a processing resource (not shown) may refer to a measurable quantity of a processing-relevant resource type, which can be requested, allocated, and consumed. A processing-relevant resource type may encompass a physical device (i.e., hardware), a logical intelligence (i.e., software), or a combination thereof, which may provide processing or computing functionality and/or services. Examples of a processing-relevant resource type may include (but not limited to): a central processing unit (CPU), a graphics processing unit (GPU), a data processing unit (DPU), a computation acceleration resource, an application-specific integrated circuit (ASIC), a digital signal processor for facilitating high speed communication, etc.

In one or more embodiments, a storage or memory resource (not shown) may refer to a measurable quantity of a storage/memory-relevant resource type, which can be requested, allocated, and consumed (for example, to store sensor data and provide previously stored data). A storage/memory-relevant resource type may encompass a physical device, a logical intelligence, or a combination thereof, which may provide temporary or permanent data storage functionality and/or services. Examples of a storage/memory-relevant resource type may be (but not limited to): a hard disk drive (HDD), a solid-state drive (SSD), random access memory (RAM), Flash memory, a tape drive, a fibre-channel (FC) based storage device, a floppy disk, a diskette, a compact disc (CD), a digital versatile disc (DVD), a non-volatile memory express (NVMe) device, a NVMe over Fabrics (NVMe-oF) device, resistive RAM (ReRAM), persistent memory (PMEM), virtualized storage, virtualized memory, etc.

In one or more embodiments, while the clients (e.g., 110A, 110N, etc.) provide computer-implemented services to users, the clients may store data that may be relevant to the users to the storage/memory resources. When the user-relevant data is stored (temporarily or permanently), the user-relevant data may be subjected to loss, inaccessibility, or other undesirable characteristics based on the operation of the storage/memory resources.

To mitigate, limit, and/or prevent such undesirable characteristics, users of the clients (e.g., 110A, 110N, etc.) may enter into agreements (e.g., SLAs) with providers (e.g., vendors) of the storage/memory resources. These agreements may limit the potential exposure of user-relevant data to undesirable characteristics. These agreements may, for example, require duplication of the user-relevant data to other locations so that if the storage/memory resources fail, another copy (or other data structure usable to recover the data on the storage/memory resources) of the user-relevant data may be obtained. These agreements may specify other types of activities to be performed with respect to the storage/memory resources without departing from the scope of the embodiments disclosed herein.

In one or more embodiments, a networking resource (not shown) may refer to a measurable quantity of a networking-relevant resource type, which can be requested, allocated, and consumed. A networking-relevant resource type may encompass a physical device, a logical intelligence, or a combination thereof, which may provide network connectivity functionality and/or services. Examples of a networking-relevant resource type may include (but not limited to): a network interface card (NIC), a network adapter, a network processor, etc.

In one or more embodiments, a networking resource may provide capabilities to interface a client with external entities (e.g., IHS A (111A), the database (101), etc.) and to allow for the transmission and receipt of data with those entities. A networking resource may communicate via any suitable form of wired interface (e.g., Ethernet, fiber optic, serial communication etc.) and/or wireless interface, and may utilize one or more protocols (e.g., transport control protocol (TCP), user datagram protocol (UDP), RDMA, RDMA over Converged Ethernet (ROCE), IEEE 801.11, etc.) for the transmission and receipt of data.

In one or more embodiments, a networking resource may implement and/or support the above-mentioned protocols to enable the communication between the client and the external entities. For example, a networking resource may enable the client to be operatively connected, via Ethernet, using a TCP protocol to form a “network fabric”, and may enable the communication of data between the client and the external entities. In one or more embodiments, each client may be given a unique identifier (e.g., an Internet Protocol (IP) address) to be used when utilizing the above-mentioned protocols.

Further, a networking resource, when using a certain protocol or a variant thereof, may support streamlined access to storage/memory media of other clients (e.g., 110A, 110N, etc.). For example, when utilizing Remote DMA (“RDMA”), e.g., RoCE to access data on another client, it may not be necessary to interact with the logical components of that client. Rather, when using RDMA, it may be possible for the networking resource to interact with the physical components of that client to retrieve and/or transmit data, thereby avoiding any higher-level processing by the logical components executing on that client.

In one or more embodiments, a virtualization resource (not shown) may refer to a measurable quantity of a virtualization-relevant resource type (e.g., a virtual hardware component), which can be requested, allocated, and consumed, as a replacement for a physical hardware component. A virtualization-relevant resource type may encompass a physical device, a logical intelligence, or a combination thereof, which may provide computing abstraction functionality and/or services. Examples of a virtualization-relevant resource type may include (but not limited to): a virtual server, a VM, a container, a virtual CPU (vCPU), a virtual storage pool, etc.

In one or more embodiments, a virtualization resource may include a hypervisor (e.g., a VM monitor), in which the hypervisor may be configured to orchestrate an operation of, for example, a VM by allocating computing resources of a client (e.g., 110A, 110N, etc.) to the VM. In one or more embodiments, the hypervisor may be a physical device including circuitry. The physical device may be, for example (but not limited to): a field-programmable gate array (FPGA), an application-specific integrated circuit, a programmable processor, a microcontroller, a digital signal processor, etc. The physical device may be adapted to provide the functionality of the hypervisor. Alternatively, in one or more of embodiments, the hypervisor may be implemented as computer instructions stored on storage/memory resources of the client that when executed by processing resources of the client, cause the client to provide the functionality of the hypervisor.

In one or more embodiments, a client (e.g., 110A, 110N, etc.) may be, for example (but not limited to): a physical computing device, a smartphone, a tablet, a wearable, a gadget, a closed-circuit television (CCTV) camera, a music player, a game controller, etc.

Different clients may have different computational capabilities. In one or more embodiments, Client A (110A) may have 16 GB of dynamic RAM (DRAM) and 1 CPU with 12 cores, whereas Client N (110N) may have 8 GB of PMEM and 1 CPU with 16 cores. Other different computational capabilities of the clients not listed above may also be considered without departing from the scope of the embodiments disclosed herein.

Further, in one or more embodiments, a client (e.g., 110A, 110N, etc.) may be implemented as a computing device (e.g., 500, FIG. 5). The computing device may be, for example, a desktop computer, a server, a distributed computing system, or a cloud resource. The computing device may include one or more processors, memory (e.g., RAM), GPUS, and persistent storage (e.g., HDDs, SSDs, etc.). The computing device may include instructions, stored in the persistent storage, that when executed by the processor(s) of the computing device cause the computing device to perform the functionality of the client described throughout the application.

Alternatively, in one or more embodiments, the client (e.g., 110A, 110N, etc.) may be implemented as a logical device (e.g., a VM, an application executing on one or more hardware components, etc.). The logical device may utilize the computing resources of any number of computing devices to provide the functionality of the client described throughout this application.

In one or more embodiments, users (e.g., administrators, organization executives, customers, people, etc.) may interact with (or operate) the clients (e.g., 110A, 110N, etc.) in order to perform work-related tasks (e.g., production workloads). In one or more embodiments, the accessibility of users to the clients may depend on a regulation set by an administrator of the clients. To this end, each user may have a personalized user account that may, for example, grant access to certain data, applications, and computing resources of the clients. This may be realized by implementing virtualization technology. In one or more embodiments, an administrator may be a user with permission (e.g., a user that has root-level access) to make changes to the clients that would affect other users of the clients.

In one or more embodiments, for example, a user may be automatically directed to a login screen of a client when the user connected to that client. Once the login screen of the client is displayed, the user may enter credentials (e.g., username, password, etc.) of the user on the login screen. The login screen may be a GUI generated by a visualization module (not shown) of the client. In one or more embodiments, the visualization module may be implemented in hardware (e.g., circuitry), software, or any combination thereof.

In one or more embodiments, a GUI may be displayed on a display of a computing device (e.g., 500, FIG. 5) using functionalities of a display engine (not shown), in which the display engine is operatively connected to the computing device. The display engine may be implemented using hardware (or a hardware component), software (or a software component), or any combination thereof. The login screen may be displayed in any visual format that would allow the user to easily comprehend (e.g., read and parse) the listed information.

In one or more embodiments, an IHS of the IHSs (e.g., 111A, 111N, etc.) may include functionality to, e.g.: (i) obtain (or receive) data (e.g., any type and/or quantity of input) from any source (and, if necessary, aggregate the data); (ii) process/analyze data that is received from one or more clients (e.g., 110A, 110N, etc.) to generate additional data that is derived from the obtained data without experiencing any middleware and hardware limitations; (iii) provide meaningful information (e.g., a response) back to the corresponding clients; (iv) filter data (e.g., received from a client) before pushing the data (and/or the derived data) to the storage for management of the data and/or for storage of the data (while pushing the data, the IHS may include information regarding a source of the data (e.g., an identifier of the source) so that such information may be used to associate provided data with one or more of the users (or data owners)); (v) host and maintain various workloads; (vi) provide a computing environment whereon workloads may be implemented (e.g., employing linear, non-linear, and/or AI/ML models to perform cloud-based data processing); (vii) incorporate strategies (e.g., strategies to provide VDI capabilities) for remotely enhancing capabilities of the clients; (viii) provide robust security features to the clients and make sure that a minimum level of service is always provided to a user of a client; (ix) transmit the result(s) of the computing work performed (e.g., real-time business insights, equipment maintenance predictions, other actionable responses, etc.) to another IHS for review and/or other human interactions; (x) exchange data with other devices registered in/to the network (130) in order to, for example, participate in a collaborative workload placement (e.g., the IHS may split up a request (e.g., an operation, a task, an activity, etc.) with another IHS, coordinating its efforts to complete the request more efficiently than if the IHS had been responsible for completing the request); (xi) provide software-defined data protection for the clients (e.g., 110A, 110N, etc.); (xii) provide automated data discovery, protection, management, and recovery operations for the clients; (xiii) monitor operational states of the clients; (xiv) regularly back up configuration information of the clients to a storage system (e.g., 145A, 145N, FIG. 1.2); (xv) provide (e.g., via a broadcast, multicast, or unicast mechanism) information (e.g., a location identifier, the amount of available resources, etc.) associated with the IHS to other IHSs of the system (100); (xvi) configure or control any mechanism that defines when, how, and what data to provide to the clients and/or to the database; (xvii) provide data deduplication to the clients (in conjunction with the storage system); (xviii) orchestrate data protection through one or more GUIs; (xix) empower data owners (e.g., users of the clients) to perform self-service data backup and restore operations from their native applications; (xx) ensure compliance and satisfy different types of service level objectives (SLOs) set by an administrator/user; (xxi) increase resiliency of an organization by enabling rapid recovery or cloud disaster recovery from cyber incidents; (xxii) provide operational simplicity, agility, and flexibility for physical, virtual, and cloud-native environments; (xxiii) consolidate multiple data process or protection requests (received from, for example, clients) so that duplicative operations (which may not be useful for restoration purposes) are not generated; (xxiv) initiate multiple data process or protection operations in parallel (e.g., an IHS may host multiple operations, in which each of the multiple operations may (a) manage the initiation of a respective operation and (b) operate concurrently to initiate multiple operations); and/or (xxv) manage operations of one or more clients (e.g., receiving information from the clients regarding changes in the operation of the clients) to improve their operations (e.g., improve the quality of data being generated, decrease the computing resources cost of generating data, etc.). In one or more embodiments, in order to read, write, or store data, the IHS (e.g., 111A, 111N, etc.) may communicate with, for example, the database (101) and/or other storage devices in the system (100).

In one or more embodiments, because technology and information handling needs vary between different users or applications, IHSs (e.g., 111A, 111N, etc.) may also vary regarding what information/data is handled, how the information is handled, how much information is processed, stored, or communicated, and how quickly and efficiently the information may be processed, stored, or communicated. The variations in IHSs may allow for the IHSs to be general or configured for a specific user or specific use such as financial transaction processing, airline reservations, enterprise data storage, or global communications. In addition, IHSs (e.g., 111A, 111N, etc.) may include a variety of hardware and software components that may be configured to process, store, and communicate information and may include one or more computer systems, data storage systems, and networking systems.

As described above, an IHS (e.g., 111A, 111N, etc.) may be capable of providing a range of functionalities/services to the users of the clients (e.g., 110A, 110N, etc.). However, not all users may be allowed to receive all the services. To manage the services provided to the users of the clients, a service manager (not shown) in accordance with embodiments disclosed herein may manage the operation of the network (130), in which the clients are operably connected to the IHSs over the network. Specifically, the service manager (i) may identify services to be provided by the IHSs (for example, based on the number of users using the clients) and (ii) may limit communications of the clients to receive IHS provided services.

For example, the priority (e.g., the user access level) of a user may be used to determine how to manage computing resources of IHS A (140A) to provide services to that user. As yet another example, the priority of a user may be used to identify the services that need to be provided to that user. As yet another example, the priority of a user may be used to determine how quickly communications (for the purposes of providing services in cooperation with the internal network (and its subcomponents)) are to be processed by the internal network.

Further, consider a scenario where a first user is to be treated as a normal user (e.g., a non-privileged user, a user with a user access level/tier of 4/10, a low-priority user, etc.). In such a scenario, the user level of that user may indicate that certain ports (of the subcomponents of the network corresponding to communication protocols such as the TCP, the UDP, etc.) are to be opened, other ports are to be blocked/disabled so that (i) certain services are to be provided to the user by IHS N (111N) (e.g., while the computing resources of IHS N may be capable of providing/performing any number of remote computer-implemented services, they may be limited in providing some of the services over the network enabled/provided by the network (130)) and (ii) network traffic from that user is to be afforded a normal level of quality (e.g., a normal processing rate with a limited communication bandwidth (BW)). By doing so, (i) computer-implemented services provided to the users of the clients (e.g., 110A, 110N, etc.) may be granularly configured without modifying the operation(s) of the clients and (ii) the overhead for managing the services of the clients may be reduced by not requiring modification of the operation(s) of the clients directly.

In contrast, a second user may be determined to be a high priority user (e.g., a privileged user, a user with a user access level of 9/10, a high-priority user, etc.). In such a case, the user level of that user may indicate that more ports are to be opened than were for the first user so that (i) IHS A (111A) may provide more services to the second user and (ii) network traffic from that user is to be afforded a high-level of quality (e.g., a higher processing rate than the traffic from the normal user).

As used herein, a “workload” may be a physical or logical component configured to perform certain work functions. Workloads may be instantiated and operated while consuming computing resources allocated thereto. A user may configure a data protection policy for various workload types. Examples of a workload may include (but not limited to): an AI workload, a data protection workload, a VM, a container, a network-attached storage (NAS), a database, an application, a collection of microservices, a file system (FS), small workloads with lower priority workloads (e.g., FS host data, operating system (OS) data, etc.), medium workloads with higher priority (e.g., VM with FS data, network data management protocol (NDMP) data, etc.), large workloads with critical priority (e.g., mission critical application data), etc.

As used herein, a “policy” is a collection of information, such as a backup policy or other data protection policy, that includes, for example (but not limited to): identity of source data that is to be protected, backup schedule and retention requirements for backed up source data, identity of an SLA (or a rule) that applies to source data, identity of a target device where source data is to be stored, etc.

As used herein, the term “backup” is intended to be broad in scope. In this manner, example backups (in connection with which embodiments disclosed herein) may be employed include (but not limited to): full backups, partial backups, clones, snapshots, incremental backups, differential backups, etc.

As used herein, “data retention” is a period of time, with a definite start and end, within which the data should be retained in a storage device (e.g., 105). For example, a set of user requirements and/or technical considerations (e.g., security considerations, performance considerations, etc.) of a data center may be used to generate a data retention policy specifying that user data should be retained in the database for seven years.

As used herein, a “rule” is a guideline used by an SLA component to select a particular target device (or target devices), based on the ability of the target device to meet requirements imposed by the SLA. For example, a rule may specify that an HDD having a particular performance parameter should be used as the target device. A target device selected by the SLA component may be identified as part of a backup policy or other data protection policy.

Further, while a single IHS (e.g., 111A) is considered above, the term “IHS” includes any collection of systems or sub-systems that individually or jointly execute a set, or multiple sets, of instructions to provide one or more computer-implemented services. For example, a single IHS may provide a computer-implemented service on its own (i.e., independently) while other IHSs may provide a second computer-implemented service cooperatively (e.g., each of the other IHSs may provide similar or different services that form the cooperatively provided service).

In one or more embodiments, an IHS (e.g., 111A, 111N, etc.) may implement a management model to manage the aforementioned computing resources in a particular manner. The management model may give rise to additional functionalities for the computing resources. For example, the management model may automatically store multiple copies of data in multiple locations when a single write of the data is received. By doing so, a loss of a single copy of the data may not result in a complete loss of the data. Other management models may include, for example, adding additional information to stored data to improve its ability to be recovered, methods of communicating with other devices to improve the likelihood of receiving the communications, etc. Any type and number of management models may be implemented to provide additional functionalities using the computing resources without departing from the scope of the embodiments disclosed herein.

One of ordinary skill will appreciate that an IHS (e.g., 111A, 111N, etc.) may perform other functionalities without departing from the scope of the embodiments disclosed herein. An IHS (e.g., 111A, 111N, etc.) may include/host any number of computing components/devices (e.g., Server A (112A), Server N (112N), heat exchangers, backup generators, row-level or room-level power distribution equipment, uninterruptible power supply (UPS) units, heating units, cooling units, air conditioning units, networking components, etc.). Additional details of an IHS are described below in reference to FIG. 1.2.

In one or more embodiments, an IHS (e.g., 111A, 111N, etc.) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the IHS described throughout the application.

Alternatively, in one or more embodiments, similar to a client (e.g., 110A, 110N, etc.), the IHS may also be implemented as a logical device.

Referring to FIG. 1.1, the database (101) is demonstrated as a standalone computing device/entity; however, embodiments disclosed herein are not limited as such. The database (101) may be demonstrated as part of an IHS (e.g., 111N) (e.g., as deployed to the IHS). Further, the digital twin creation and storage module (102) is demonstrated as a standalone computing device/entity; however, embodiments disclosed herein are not limited as such. The digital twin creation and storage module (102) may be demonstrated as part of an IHS (e.g., 111N) (e.g., as deployed to the IHS).

Turning now to the database (101), the database (101) may provide long-term, durable, high read/write throughput data storage/protection with near-infinite scale and low-cost. The database (101) may be a fully managed cloud/remote (or local) storage (e.g., pluggable storage, object storage, block storage, file system storage, data stream storage, Web servers, unstructured storage, etc.) that acts as a shared storage/memory resource that is functional to store unstructured and/or structured data. For example, the database (101) may store data (e.g., backup data; file system metadata; assets; rules and/or procedures for performing backups of the servers; etc.). Further, the database (101) may also occupy a portion of a physical storage/memory device or, alternatively, may span across multiple physical storage/memory devices. The database (101) may include other and/or additional functionalities without departing from embodiments disclosed herein.

In one or more embodiments, the database (101) may be implemented using physical devices that provide data storage services (e.g., storing data and providing copies of previously stored data). The devices that provide data storage services may include hardware devices and/or logical devices. For example, the database (101) may include any quantity and/or combination of memory devices (i.e., volatile storage), long-term storage devices (i.e., persistent storage), other types of hardware devices that may provide short-term and/or long-term data storage services, and/or logical storage devices (e.g., virtual persistent storage/virtual volatile storage).

For example, the database (101) may include a memory device (e.g., a dual in-line memory device), in which data is stored and from which copies of previously stored data are provided. As yet another example, the database (101) may include a persistent storage device (e.g., an SSD), in which data is stored and from which copies of previously stored data is provided. As yet another example, the database (101) may include (i) a memory device in which data is stored and from which copies of previously stored data are provided and (ii) a persistent storage device that stores a copy of the data stored in the memory device (e.g., to provide a copy of the data in the event that power loss or other issues with the memory device that may impact its ability to maintain the copy of the data).

Further, the database (101) may also be implemented using logical storage. Logical storage (e.g., virtual disk) may be implemented using one or more physical storage devices whose storage resources (all, or a portion) are allocated for use using a software layer. Thus, logical storage may include both physical storage devices and an entity executing on a processor or another hardware device that allocates storage resources of the physical storage devices.

In one or more embodiments, the database (101) may store/log/record unstructured and/or structured data that may include (or specify), for example (but not limited to): a backup policy/practice; telemetry data including past and present device usage of one or more computing devices; data for execution of applications/services including server applications and associated end-points; corpuses of annotated data used to build/generate and train processing classifiers for trained ML/AI models; linear, non-linear, and/or AI model parameters; data tags; an identifier of a sensor; a product identifier of a client (e.g., 110A); a type of a client; historical sensor data/input (e.g., visual sensor data, audio sensor data, electromagnetic radiation sensor data, temperature sensor data, humidity sensor data, corrosion sensor data, etc., in the form of text, audio, video, touch, and/or motion) and its corresponding details; an identifier of a data item; a size of the data item; an identifier of a user (e.g., a unique string or combination of bits associated with a particular user) who initiated a backup (via a client); a distributed model identifier that uniquely identifies a distributed model; a user activity performed on a data item; a cumulative history of user/administrator activity records obtained over a prolonged period of time; a setting (and a version) of a mission critical application/workload executing on a server (e.g., 112A); configuration information associated with a server (e.g., 112A); a job detail of a job that has been initiated by a server (e.g., 112A); a type of the job (e.g., a non-parallel processing job, a parallel processing job, an analytics job, etc.); information associated with a hardware resource set (discussed below) of a server (e.g., 112A); a completion timestamp encoding a date and/or time reflective of the successful completion of a job/workload; a time duration reflecting the length of time expended for executing and completing a job; a backup retention period associated with an asset (e.g., data item); a status of a job (e.g., how many jobs are still active, how many jobs are completed, etc.); a number of requests handled (in parallel) per minute (or per second, per hour, etc.) by a server (e.g., 112A); a number of errors encountered when handling a job (e.g., a backup process); a documentation that shows how a server (e.g., 112A) performs against an SLO and/or an SLA; a set of requests received by a server (e.g., 112A); a set of responses provided (by the server) to those requests; information regarding an administrator (e.g., a high-priority trusted administrator, a low-priority trusted administrator, etc.) related to a job; tier/level information of a user (e.g., a high-priority user, a low-priority user, etc.); a geographic location (e.g., a country) associated with the user; a timestamp showing when a specific request is processed by a server (e.g., 112A); computing resource details (including details of hardware components and/or software components) and an IP address of a server (e.g., 112A) hosting an application where a specific request is processed; information with respect to historical metadata (e.g., system logs, applications logs, telemetry data including past and present device usage of one or more computing devices in the system (100), etc.); computing resource details and an IP address of a client that sent a specific request (e.g., to a server); an existing knowledge base (KB) article; a technical support history documentation of a customer/user; a port's user guide; a port's release note; a community forum question and its associated answer; a catalog file of an application upgrade; details of a compatible OS version for an application upgrade to be installed; an application upgrade sequence; a solution or a workaround document for a software failure; one or more lists that specify which computer-implemented services should be provided to which user (depending on a user access level of a user); a fraud report for an invalid user; a set of SLAs (e.g., an agreement that indicates a period of time required to retain a profile of a user); information with respect to a user/customer experience; checkpoint data; data used for AI model training and/or AI inferencing; a record that is associated with a digital twin of a workload; a record that is associated with a digital twin of a server; a record that is associated with a digital twin of an IHS; historical data associated with one or more workloads; etc.

In one or more embodiments, information associated with a hardware resource set (e.g., including at least resource related parameters) may specify, for example (but not limited to): a configurable CPU option (e.g., a valid/legitimate vCPU count for a server (e.g., 112A)), a configurable network resource option (e.g., enabling/disabling single-root input/output virtualization (SR-IOV) for the server), a configurable memory option (e.g., maximum and minimum memory for the server), a configurable GPU option (e.g., allowable scheduling policy and/or virtual GPU (vGPU) count combinations for the server), a configurable DPU option (e.g., legitimacy of disabling inter-integrated circuit (I2C) for the server), a configurable storage space option (e.g., a list of disk cloning technologies across one or more servers in the system (100)), a configurable storage I/O option (e.g., a list of possible file system block sizes across all target file systems), a user type (e.g., a knowledge worker, a task worker with relatively low-end compute requirements, a high-end user that requires a rich multimedia experience, etc.), a network resource related template (e.g., a 10 GB/s BW with 20 ms latency quality of service (QoS) template), a DPU related template (e.g., a 1 GB/s BW vDPU with 1 GB vDPU frame buffer template), a GPU related template (e.g., a depth-first vGPU with 1 GB vGPU frame buffer template), a storage space related template (e.g., a 40 GB SSD storage template), a CPU related template (e.g., a 1 vCPU with 4 cores template), a memory resource related template (e.g., an 8 GB DRAM template), a vCPU count per analytics engine, a virtual NIC (vNIC) count per server in the system (100), a wake on LAN support configuration (e.g., supported/enabled, not supported/disabled, etc.), a vGPU count per server in the system (100), a type of a vGPU scheduling policy (e.g., a “fixed share” vGPU scheduling policy), a storage mode configuration (e.g., an enabled high-performance storage array mode), etc.

While the database (101) has been illustrated and described as including a limited number and type of data, the database (101) may store additional, less, and/or different data without departing from the scope of the embodiments disclosed herein. One of ordinary skill will appreciate that the database (101) may perform other functionalities without departing from the scope of the embodiments disclosed herein.

Referring to FIG. 1.1, the system (100) further includes the digital twin creation and storage module (102). The digital twin creation and storage module (102) may include functionality for generating, storing, updating, providing, using, and/or otherwise managing a set/library of digital twins that each correspond to an entity/component (e.g., a hardware component (or a hardware computing resource) digital twin, a workload digital twin, a server digital twin, an IHS digital twin, etc.). Any other entity may be described using a digital twin without departing from the scope of the embodiments disclosed herein. Additional details of the digital twin module are described below in reference to FIG. 1.3.

In one or more embodiments, the digital twin creation and storage module (102) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the digital twin module described throughout the application.

Alternatively, in one or more embodiments, similar to a client (e.g., 110A, 110N, etc.), the digital twin module may also be implemented as a logical device.

In one or more embodiments, any computing device (e.g., Server A (112A)) of an IHS (e.g., 111A), the clients (e.g., 110A, 110N, etc.), the database (101), and the digital twin creation and storage module (102) may be powered by the power grid (120). The power grid (120) may be an extensive cross-country network that includes sources of power used to enable electricity distribution to the aforementioned components (to enable, at least, each component's operations).

As indicated above, the power grid (120) may emit energy/electricity to the aforementioned components/computing devices and may include (or connected to) one or more power generating/generation sources/generators (e.g., power plants (e.g., nuclear power plants, natural gas power plants, coal-fired power plants, hydropower plants, etc.), dams, solar farms, wind farms, etc.). The power grid (120) may include a system of interconnected entities that generate, transmit, and distribute power to the aforementioned components. The power grid (120) may include an infrastructure that connects the power sources to the aforementioned components.

In one or more embodiments, the generation of power by the power grid (120) to provide electricity to the aforementioned components/computing devices may result in grid emissions (e.g., average emissions). Grid emissions may refer to an environmental impact that results in the production of power for use by the components/computing devices of the system (100). The environmental impact includes the emission of greenhouse gases, such as carbon dioxide, by power generating sources. Each of the aforementioned power generating sources may correspond to a level of grid emission based on the amount of greenhouse gases emitted due to the generation of power. For example, a coal-fired power plant may correspond to a higher level of grid emissions than a hydropower plant or a wind farm.

In one or more embodiments, grid emissions caused by a given workload may be calculated (or otherwise measured) based on the amount of computing resources used to execute the workload, an amount of electricity used to power the said amount of computing resources, and a power supply profile (e.g., a type of power plant(s)) of the power grid (120) used to supply the said amount of electricity. Such calculated (or otherwise measured) grid emissions may be stored in a corresponding workload report of the given workload.

In one or more embodiments, all, or a portion, of the components of the system (100) may be operably connected each other and/or other entities via any combination of wired and/or wireless connections. For example, the aforementioned components may be operably connected, at least in part, via the network (130). Further, all, or a portion, of the components of the system (100) may interact with one another using any combination of wired and/or wireless communication protocols.

In one or more embodiments, the network (130) may represent a (decentralized or distributed) computing network and/or fabric configured for computing resource and/or messages exchange among registered computing devices (e.g., the clients, the IHSs, etc.). As discussed above, components of the system (100) may operatively connect to one another through the network (e.g., a storage area network (SAN), a personal area network (PAN), a LAN, a metropolitan area network (MAN), a WAN, a mobile network, a wireless LAN (WLAN), a virtual private network (VPN), an intranet, the Internet, etc.), which facilitates the communication of signals, data, and/or messages. In one or more embodiments, the network (130) may be implemented using any combination of wired and/or wireless network topologies, and the network may be operably connected to the Internet or other networks. Further, the network (130) may enable interactions between, for example, the clients and the IHSs through any number and type of wired and/or wireless network protocols (e.g., TCP, UDP, IPv4, etc.).

The network (130) may encompass various interconnected, network-enabled subcomponents (not shown) (e.g., switches, routers, gateways, cables etc.) that may facilitate communications between the components of the system (100). In one or more embodiments, the network-enabled subcomponents may be capable of: (i) performing one or more communication schemes (e.g., IP communications, Ethernet communications, etc.), (ii) being configured by one or more components in the network, and (iii) limiting communication(s) on a granular level (e.g., on a per-port level, on a per-sending device level, etc.). The network (130) and its subcomponents may be implemented using hardware, software, or any combination thereof.

In one or more embodiments, before communicating data over the network (130), the data may first be broken into smaller batches (e.g., data packets) so that larger size data can be communicated efficiently. For this reason, the network-enabled subcomponents may break data into data packets. The network-enabled subcomponents may then route each data packet in the network (130) to distribute network traffic uniformly.

In one or more embodiments, the network-enabled subcomponents may decide how real-time (e.g., on the order of microseconds or less) network traffic and non-real-time network traffic should be managed in the network (130). In one or more embodiments, the real-time network traffic may be high-priority (e.g., urgent, immediate, etc.) network traffic. For this reason, data packets of the real-time network traffic may need to be prioritized in the network (130). The real-time network traffic may include data packets related to, for example (but not limited to): videoconferencing, web browsing, voice over Internet Protocol (VOIP), etc.

While FIG. 1.1 shows a configuration of components, other system configurations may be used without departing from the scope of the embodiments disclosed herein.

In one or more embodiments, the system (100) further includes any number of AI agents (109). The AI agents (109) may include functionality for performing any AI inferencing, AI training, or other AI workloads using data obtained using any component such as, for example, the IHSs (11A, 11N).

For example, the AI agents (109) may include functionality for initiating workloads based on processed data and/or based on logic applied to the processed data. The workloads may be initiated in response to a determination that a workload is to be executed. Such determination may be automated (e.g., without the decision made by a user). Any processing may be performed to make such determinations without departing from the invention.

In one or more embodiments, the AI agents (109) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the digital twin module described throughout the application.

Alternatively, in one or more embodiments, similar to a client (e.g., 110A, 110N, etc.), the AI agents (109) may also be implemented as a logical device.

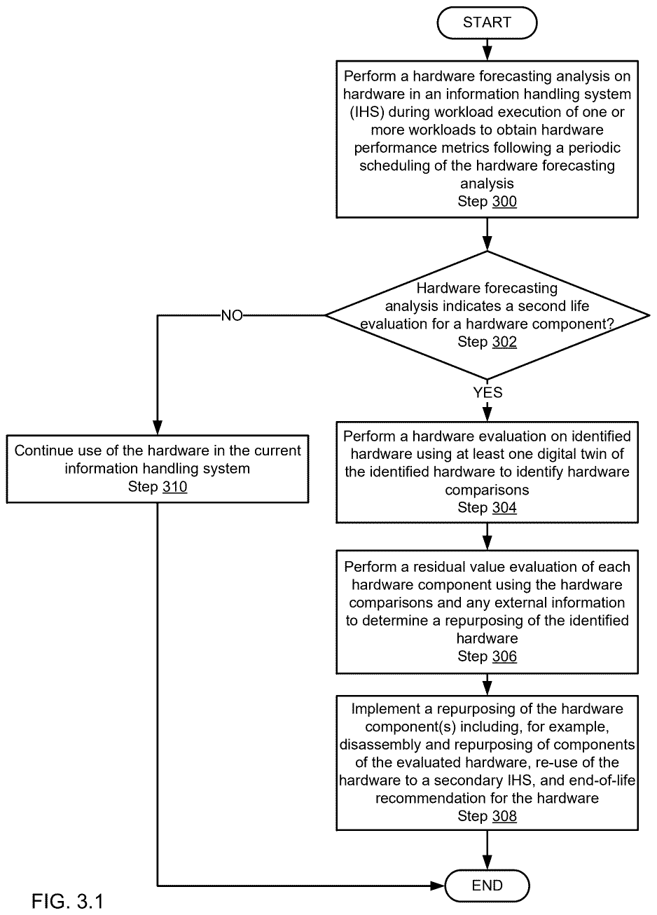

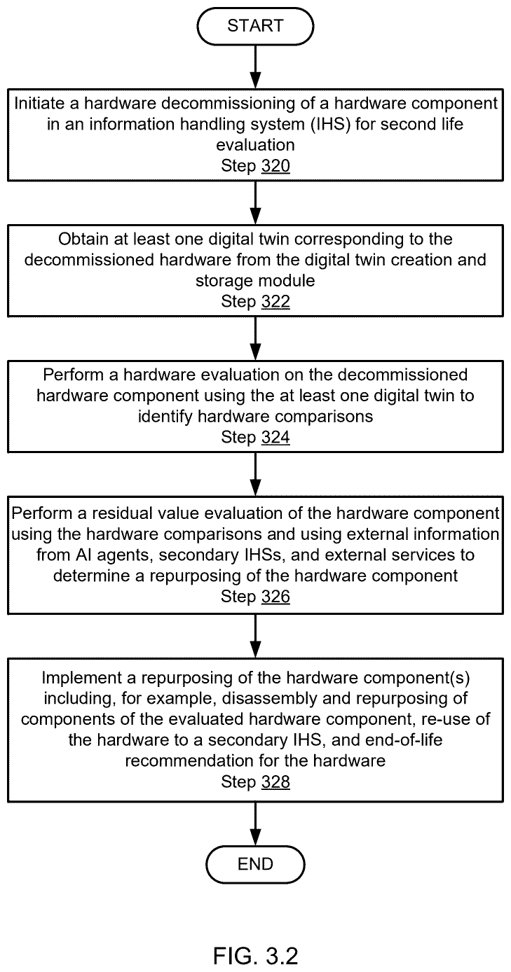

In one or more embodiments, the system (100) further includes the second life evaluation service (190). The second life evaluation service (190) may include functionality for performing a second life evaluation of hardware in the IHSs (111A, 111N) to identify any repurposing of the hardware that is to be performed. As the hardware of the IHSs (111A, 111N) are used for the operation of the IHSs (111A, 111N) described throughout the present disclosure, the physical hardware may experience degradation. After some degradation has occurred, the physical hardware may perform at a lower level of accuracy and speed than the beginning of the hardware lifecycle. Given the lower level of performance, the hardware, after some degradation, may be more suited for a different purpose. The second life evaluation service (190) may include functionality for evaluating the performance of the hardware and to determine the different purpose of the given hardware. Such determination may be performed in accordance with the methods of FIGS. 3.1-3.2. Other methods may be performed to make such determination without departing from the invention.

In one or more embodiments, the second life evaluation service (190) may be implemented as a computing device (e.g., 500, FIG. 5). The computing device may be, for example, a mobile phone, a tablet computer, a laptop computer, a desktop computer, a server, a distributed computing system, or a cloud resource. The computing device may include one or more processors, memory (e.g., RAM), GPUs, and persistent storage (e.g., HDDs, SSDs, etc.). The computing device may include instructions, stored in the persistent storage, that when executed by the processor(s) of the computing device cause the computing device to perform the functionality of the digital twin module described throughout the application.

Alternatively, in one or more embodiments, similar to a client (e.g., 110A, 110N, etc.), the second life evaluation service (190) may also be implemented as a logical device.

Turning now to FIG. 1.2, FIG. 1.2 shows a diagram of an IHS (e.g., IHS A (111A)) in accordance with one or more embodiments disclosed herein. More specifically, FIG. 1.2 shows additional details of an IHS (e.g., a small data center in a factory, a cloud device, a manufacturing execution subsystem, etc.) in accordance with one or more embodiments disclosed herein. As being a physical computing device, IHS A (111A) may include hardware such as one or more racks (not shown), networking systems (115A, 115N), storage systems (145A, 145N), power distribution units (PDUs) (146A, 146N), backup power supplies (147A, 147N), a set of servers (e.g., 112A, 112N, etc.), internal and external factors data collector and tracker (IEFDCT) (122), user interfaces (126) that includes a report engine (117), a policy engine (120), a workload orchestration system (103), and a hardware management system (140). IHS A (111A) may include additional, fewer, and/or different components without departing from the scope of the embodiments disclosed herein. Each component may be operably connected to any of the other components via any combination of wired and/or wireless connections. Each component illustrated in FIG. 1.2 is discussed below.

In one or more embodiments, the rack may be a chassis (e.g., a mechanical structure) that is configured to house/host one or more computing devices (or blades) (e.g., 112A, 112N, etc.) and their components, to be positioned with respect to one another. For example, the rack may be a mountable enclosure that enables the computing devices (e.g., 112A, 112N, etc.) to be disposed within the rack. The rack may be implemented as other types of structures adapted to host, position, orient, and/or otherwise physically, mechanically, electrically, and/or thermally manage the computing devices. By managing the computing devices, the rack may enable the computing devices to be densely packed in a space without negatively impacting the operation of IHS A (111A).

In one or more embodiments, as being a physical computing device, a server (e.g., 112A, 112N, etc.) may be a mechanical structure for housing hardware components (or hardware computing resources). For example, the server (e.g., 112A, 112N, etc.) may be implemented as a rack mountable enclosure for housing hardware components. The server (e.g., 112A, 112N, etc.) may be adapted to be disposed within the rack, and/or utilize services provided by the rack and/or other components available in the system (e.g., 100, FIG. 1.1).

In one or more embodiments, the server (e.g., 112A, 112N, etc.) may have any instrumentality or aggregate of instrumentalities (e.g., a hardware layer (113), a software layer (114), etc.) operable to compute, classify, process, transmit, receive, retrieve, originate, switch, store, display, manifest, detect, record, reproduce, handle, and/or utilize any form of data for business, management, entertainment, or other purposes. The server (e.g., 112A, 112N, etc.) may provide any quantity and any type of computer-implemented services, for example, to users of a client (e.g., 110A, FIG. 1.1). To provide computer-implemented services, the server (e.g., 112A, 112N, etc.) may be a heterogeneous set, including a collection of physical “computing” components/resources (e.g., 113) configured to perform operations of the server and/or otherwise execute a collection of logical “computing” components/resources (e.g., 114) of the server. As used herein, a computing resource may be a measurable quantity of a compute-relevant resource type that may be requested, allocated, and/or consumed.

In one or more embodiments, the hardware layer (113) may represent the collection of physical hardware components/resources (e.g., a hardware resource set, see FIG. 1.1), and the software layer (114) may represent the collection of logical “computing” components (e.g., applications (and/or content accessible through applications), virtualization resources (see FIG. 1.1), etc.). A physical hardware component of the hardware layer (113) may be (or may be implemented as), for example (but not limited to): a processing resource (e.g., CPU, a GPU, a tensor processing unit (TPU), a neural processing unit (NPU), etc., see FIG. 1.1), a networking resource (e.g., a NIC, a peripheral interface express (PCIe) device, etc., see FIG. 1.1), a storage/memory resource (e.g., an SSD, an HDD, Flash memory, etc., see FIG. 1.1), a memory management unit (MMU), etc.

In one or more embodiments, the server (e.g., 112A, 112N, etc.) may include functionality to execute one or more workloads (e.g., AI (or AI model) training workloads, AI inferencing workloads, etc.) using the hardware layer (113) and/or the software layer (114). For example, the server may include a local AI application (not shown) that manages the execution of various AI workloads on the hardware layer. In one or more embodiments, the server (e.g., 112A, 112N, etc.) may be operatively connected to another server (e.g., to transmit data, to receive data, etc.) via a networking system (e.g., 115A) such as, for example, a top-of-rack (ToR) switch when the servers are in the same server rack, or via a scale-out network (e.g., 130, FIG. 1.1) when the servers are in different server racks and/or in different geographic locations/zones across the world.

The server (e.g., 112A, 112N, etc.) may include additional, fewer, and/or different components without departing from the scope of the embodiments disclosed herein. One of ordinary skill will appreciate that the server (e.g., 112A, 112N, etc.) may perform other functionalities without departing from the scope of the embodiments disclosed herein.

In one or more embodiments, as being a physical computing device or a logical computing device, the policy engine (132) may be configured to manage policies implemented by the IHS (111A). One of ordinary skill will appreciate that policy engine (132) may perform other functionalities without departing from the scope of the embodiments disclosed herein. The policy engine (132) may be implemented as a computing device using hardware (e.g., any number of integrated circuits for processing computer readable instructions), software (e.g., a computer program), or any combination thereof.

In one or more embodiments, as being a physical computing device or a logical computing device, the internal and external factors data collector and tracker (IEFDCT) (122) includes functionality to, at least obtain/retrieve real-time (or near-real-time) internal factors data and external factors data (including, at least, environmental conditions) from corresponding entities, and provide aforementioned the data to the workload orchestration system (103) to make more informed decisions for workload scheduling/deployment.

In one or more embodiments, as being a physical computing device or a logical computing device, the workload orchestration system (103) may include a workload lifecycle manager (134), a workload instantiation engine (WIE) (104), a workload scheduler (105), a workload queue (106), any number of active workload digital twins (107), and a workload reporter (108).

In one or more embodiments, the workload orchestration system (103) includes functionality to, at least: (i) manage, using at least the workload lifecycle manager (134), the WIE (104), and the workload scheduler (106), one or more workloads (that are received from one or more users or AI agents) in terms of scheduling/deployment (e.g., manage multiple workloads by queuing, comparing, and prioritizing based on the internal factors data, external factors data, required time to complete a related workload, and estimates of workload runtime requirements, and make informed decisions to schedule each workload accordingly); (ii) perform, using at least the workload scheduler (104), an optimized scheduling of a workload by employing a model (e.g., an optimizer ML model or a performance model of an active digital twin) and leveraging historical processing times of the workload (or a similar workload) to estimate execution duration of the workload (so that the workload can be executed efficiently and timely while minimizing carbon emissions due to execution of the workload); (iii) reduce total energy required to execute a workload by considering real-time internal factors data (e.g., IHS power distribution losses, cooling system energy requirements, etc.) so that, for example, non-urgent/critical workloads can be scheduled (or rescheduled) to a corresponding server when the cooling system overhead of a related IHS is significantly lower than average; (iv) by considering real-time external factors data, schedule a workload when grid emissions (e.g., average grid emissions) indicate a significant use of renewable resources (e.g., solar farm, wind farm, etc.) (said another way, when energy demand to execute the workload can be met with lower emission power generators) to minimize carbon emissions associated with the workload; (v) by considering real-time external factors data (e.g., current grid information on a national or global basis), schedule a workload to a server that is located in a region in the world supporting lower carbon emissions; (vi) based on (iv)-(v), reduce executional costs of a workload and minimize carbon emissions of the workload by shifting the workload to a server that is hosted in an edge device (e.g., an IHS that is located in the functional edge region), an edge node (e.g., an IHS that is located in the far edge region), or another edge node (e.g., an IHS that is located in the near edge region); (vii) using one or more feedback loops, re-train (and/or fine-tune) ML/AI models (that are used to manage/schedule workloads) to improve a related model's accuracy (in terms of producing better forecasting outcomes); (viii) implement role-specific UIs (in conjunction with the digital twin creation and storage module (e.g., 102, FIG. 1.3)), which present and contextualize information in accordance with a user's “operational” role/level; (ix) after deployment, monitor execution of a workload on a related server to obtain information (e.g., a workload report) associated with the workload from the server; (x) use a digital twin of a workload in order to capture (and store) important workload input, output, and performance characteristics; and/or (xi) communicate directly with the digital twin creation and storage module (e.g., 102, FIG. 1.3) to instruct the module for generating one or more active workload digital twins (107) of scheduled workloads in order to facilitate the use of the digital twins.

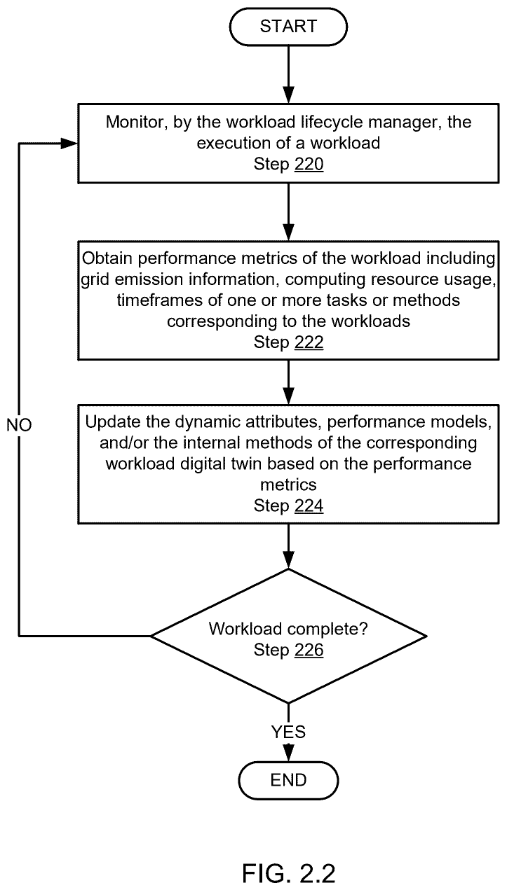

One of ordinary skill will appreciate that the workload orchestration system (103) may perform other functionalities without departing from the scope of the embodiments disclosed herein. The workload orchestration system (103) may be implemented as a computing device using hardware (e.g., any number of integrated circuits for processing computer readable instructions), software (e.g., a computer program), or any combination thereof. In one or more embodiments, the workload orchestration system (103) may be configured to perform all, or a portion, of the functionalities described in FIGS. 2.1-2.2.

While the workload orchestration system (103) is illustrated as part of IHS A (111A), the workload orchestration system (103) may be external to IHS A (111A) without departing from the scope of the embodiments disclosed herein.

In one or more embodiments, information of a workload may include, for example (but not limited to): computing resource information (associated with a server that has been assigned to execute the workload), external factors data (e.g., grid emission information) associated with the server, computing resource utilization information (indicating which computing resources of the server have been utilized to execute the workload), etc.

In one or more embodiments, computing resource information may include/specify data about the computing resources/components (of the server) involved in the execution of the workload. For example, computing resource information may include an identifier of each computing resource/device (of a server) that is used for to execute the workload and a type of each computing device.

Further, computing resource utilization information may be a combination of time series that each correspond to the utilization of one of the computing resources (of the server, such as processing resources, storage/memory resources, networking resources, etc.) while executing the workload.

In one or more embodiments, grid emission information may include information calculated, or measured, about the grid emissions (e.g., average grid emissions) caused by powering the computing resources (of the server) used to execute the workload. Grid emission information may be calculated by the workload orchestration system (103) discussed above during monitoring execution of the workload. For example, grid emission information may be calculated by identifying a power resource used to power the computing resources, identifying a profile of the power resource (e.g., a type of power plant used to generate electricity), and measuring an amount of energy used to power/support the computing component utilization. Other mechanisms may be used to calculate (or measure) the grid emission information without departing from the scope of the embodiments disclosed herein.

In one or more embodiments, as being a physical computing device or a logical computing device, the hardware management system (140) may include a cluster management system (116), an IHS scheduler (141), an IHS queue (142), one or more active IHSs and server digital twins (143), and an IHS reporter (144).

In one or more embodiments, the hardware management system (140) includes functionality to, at least: (i) manage, using at least the cluster management system (116), the IHS scheduler (141), and the IHS scheduler (141), operation of one or more servers (112A, 112N) or other hardware (e.g., 115A, 115N, 145A, 145N, 146A, 146N, 147A, 147N, etc.) in terms of scheduling/deployment of workloads (e.g., by managing the availability of the hardware to determine which hardware is used for executing or deploying workloads); (ii) perform, using at least the IHS scheduler (141), an optimized scheduling of the hardware by employing a model (e.g., an optimizer ML model or a performance model of an active IHS digital twin) and leveraging historical processing times of workloads to estimate execution duration of the workloads to control the use of the hardware for workload execution; (iii) manage total energy of the hardware by considering real-time internal factors data (e.g., IHS power distribution losses, cooling system energy requirements, etc.) so that, for example, high energy consumption hardware can be scheduled (or rescheduled) to a corresponding workload when the cooling system overhead of a related IHS is significantly lower than average, or conversely, when low energy consumption hardware is scheduled to be used when the cooling system overhead is higher than average to minimize energy consumption spikes; (iv) by considering real-time external factors data, schedule use of hardware when grid emissions (e.g., average grid emissions) indicate a significant use of renewable resources (e.g., solar farm, wind farm, etc.) (said another way, when energy demand to execute the workload can be met with lower emission power generators) to minimize carbon emissions associated with the workload; (v) reduce executional costs of hardware power consumption and minimize carbon emissions of the hardware by shifting hardware assignments of workloads to, for example, a server that is hosted in an edge device (e.g., an IHS that is located in the functional edge region), an edge node (e.g., an IHS that is located in the far edge region), or another edge node (e.g., an IHS that is located in the near edge region); (vi) using one or more feedback loops, re-train (and/or fine-tune) ML/AI models (that are used to manage/schedule workloads) to improve a related model's accuracy (in terms of producing better forecasting outcomes); (vii) implement role-specific UIs (in conjunction with the digital twin creation and storage module (e.g., 102, FIG. 1.3)), which present and contextualize information in accordance with a user's “operational” role/level; (viii) after deployment, monitor computing resource usage of the hardware in the IHS; (x) use active IHS and server digital twins (143) in order to capture (and store) important hardware input, output, and performance characteristics; and/or (xi) communicate directly with the digital twin creation and storage module (e.g., 102, FIG. 1.3) to instruct the module for generating one or more active IHS and server digital twins (143) in order to facilitate the use of the server digital twins (143).

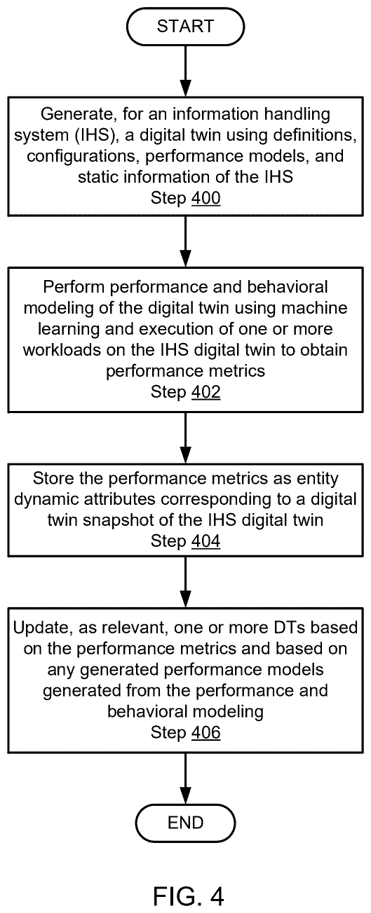

Turning now to FIG. 1.3, FIG. 1.3 shows a diagram of the digital twin creation and storage module (102) in accordance with one or more embodiments disclosed herein. More specifically, FIG. 1.3 shows additional details of the digital twin creation and storage module (102) in accordance with one or more embodiments disclosed herein. As being a physical computing device or a logical computing device, the digital twin creation and storage module (102) may include functionality for generating, storing, updating, providing, and/or otherwise using diverse operational digital twins (where each digital twin is associated with an entity) (e.g., Workload Digital Twin (DT) A (167A), Workload DT N (167N), Server DT A (168A), Server DT N (168N), IHS DT A (160A), IHS DT N (160N), etc.). The digital twin creation and storage module (102) may further include a digital twin manager (166) to perform, at least, the aforementioned functionalities, including the method of FIG. 4. The digital twin creation and storage module (102) may include additional, fewer, and/or different components without departing from the scope of the embodiments disclosed herein. Each component may be operably connected to any of the other components via any combination of wired and/or wireless connections.

In one or more embodiments, (a) Workload DT A (167A) may be a real-time digital/virtual representation of a workload (an instance of a defined class, in which the class specifies the information about the workload that is either required or would be stored, in addition to methods that enable an operation of Workload DT A), (b) Server DT A (168A) may be a real-time digital representation of a server (e.g., 112A, FIG. 1.2), and (c) IHS DT A (160A) may be a real-time digital representation of an IHS (e.g., 111A, FIG. 1.2) discussed throughout the present disclosure. As being a digital model, a digital twin (e.g., 167A, 167N, 168A, 168N, 160A, 160N, etc.) of a particular entity may include all relevant information about that entity (or represent said entity using standardized definitions, attributes, and/or other information).

In one or more embodiments, the IHS DTs (e.g., 160A, 160N) may be further defined using additional digital twins. For example, the IHS DTs (160A, 160N) may include any number of information technology (IT) asset DTs (e.g., 150A), any number of peripheral DTs (155A) and one or more workload DTs (159A, 159Z). Each IT-asset DT (e.g., 150A) of the IHS DT (e.g., 160A) may include one of, for example, a server DT (e.g., Server DT A (151A)), a storage system DT (e.g., Storage System DT A (152A)), and a networking system DT (e.g., Networking System DT A (153A)). Each peripheral DT (e.g., 155A) of the IHS DT (e.g., 160A) may include one of, for example, a rack DT (e.g., Rack DT A (156A)), a rack-mounted PDU DT (e.g., Rack-Mounted PDU DT A (157A)), and a backup power supply DT (e.g., Backup Power Supply DT A (158A)). Other hardware DTs may be used to define an IHS DT without departing from the invention.

In one or more embodiments, a digital twin (e.g., 167A, 167N, 168A, 168N, 160A, 160N, etc.) of a particular entity may include any number of snapshots (See FIG. 1.5). Each digital twin snapshot may correspond to a related digital twin at a given point in time. Each digital twin snapshot may include a definition (of a digital twin), system configurations of the corresponding entity represented by the digital twin, entity static attributes, entity dynamic attributes, one or more methods, and one or more performance models. Each digital twin snapshot may include additional, fewer, and/or different information without departing from the scope of the embodiments disclosed herein.

In one or more embodiments, a digital twin (e.g., 167A, 167N, 168A, 168N, 160A, 160N, etc.) of a particular entity may be generated using DT creation templates (165). The DT creation templates (165) may each be a pre-defined template that may be initialized based on information about a given entity, an entity type (e.g., a workload type, a server type, an IHS type, etc.). Additional details of the DT creation templates (165) are discussed in FIG. 1.4.

In one or more embodiments, as being a physical computing device or a logical computing device, the DT manager (166) may further include functionality to, at least: (i) generate and provide a portal/visualizer (e.g., a UI, a GUI, an application programming interface (API), a human-machine interface, a communication channel, an AI-based dashboard, etc.), which contextualizes information for a specific user (the manager may initially present information/metrics (on a UI) related to his/her role/level, but over time and based on previous user interactions, may tailor the metrics that better align with the user's/stakeholder's areas of interest (so that the same information can be presented in different ways to different types of users in an organization); (ii) using the RAG engine (not shown), interpret human/user queries/interactions, retrieve necessary information, and present responses to a corresponding user in a context-appropriate manner (in order to provide collaborative and non-compromised outcomes for the user); and/or (iii) using the RAG engine, ensure that different types of digital twins can support real-time querying for tailored user insights. Other functionalities of the DT manager (166) may be described using the method of FIG. 4.

One of ordinary skill will appreciate that the DT manager (166) may perform other functionalities without departing from the scope of the embodiments disclosed herein. The DT manager (166) may be implemented as a computing device using hardware (e.g., any number of integrated circuits for processing computer readable instructions), software (e.g., a computer program), or any combination thereof.

Turning to FIG. 1.4, the DT creation templates (e.g., DT Creation Template A (171A), DT Creation Template N (171N)) may each be pre-defined with at least definitions (172), configurations (173), static attributes (174), dynamic attributes (175), methods (176), and performance models (177). Other information may be used to pre-define a DT creation template (e.g., 171A, 171N) without departing from the invention.

In one or more embodiments, a definition of a digital twin (e.g., 167A, 168A, etc.) may be a standardized data structure that defines the entity (e.g., a workload, a server, an IHS, etc.) of the digital twin. The definitions (172) may include, for example, an identifier of the entity, a type of computing device(s) used to define the entity, schemas, properties, relationships to other digital twins (e.g., the relationship between an IHS digital twin (160A) and an IT-asset DT (150A) discussed above), components of the digital twin, arrays, key-value pairs, objects, classes, complex schema objects, or other information without departing from the invention.

In one or more embodiments, configurations (173) may specify one or more configurations between components, objects, interfaces, relationships in the entity. For example, the configurations (173) of a hardware entity such as a server may specify the computing resources (e.g., processors, memory, storage) configured to be used for the server.

In one or more embodiments, the attributes (174, 175) specify attributes of the entity further used to describe the entity. The static attributes (174) may refer to such attributes not intended to change between each DT snapshot (e.g., 181A, 181N, FIG. 1.5). Conversely, dynamic attributes (175) may include attributes that may change between each snapshot such as, for example, configuration changes, simulated hardware component degradation, simulated grid emissions caused by a digital twin, and other simulated performance metrics of the corresponding entity based on any use of the digital twin when executing other workloads.

In one or more embodiments, the digital twin creation and storage module (102, FIG. 1.3) may include an immutable ledger (e.g., a blockchain) to store each digital twin (e.g., 167A, 168A, 160A, etc.). As such, each digital twin snapshot may be stored and prevent modification of the information stored in the given snapshot. In one or more embodiments, the digital twin creation and storage module (102) may also be able to participate in a digital ledger outside of the embodiments disclosed herein, without including the entirety of the immutable ledger.

In one or more embodiments, a digital twin (e.g., 167A, 168A, 160A, etc.) may include the code necessary to execute specific methods (176) on or using the digital twin. This may be the case, if, for example, predictive ML model code is associated with a specific digital twin, but where full exposure of the predictive ML model is undesired. In this case, may specify the means for accessing a specific method, but may hide the actual method (for itself).

In one or more embodiments, before performing its duties, a digital twin (e.g., 167A, 168A, 160A, etc.) may first go through a modeling phase (performed by the manager (126, FIG. 1.3)) using training data (said another way, a digital twin may be a model based on specific modeling data that is decided by a corresponding organization). The modeling phase may be performed at different points-in-time, may be performed repeatedly (e.g., performing modeling, then monitoring, then modeling, then monitoring, etc.), or may otherwise be utilized to provide a digital twin's functionality. The modeling of the performance of the digital twin may be stored as one or more performance models (177) of the digital twin.

In one or more embodiments, on a UI (e.g., 118A, 118N, etc.), (i) each data item may be displayed (e.g., highlighted, visually indicated, etc.) with a different color (e.g., red color tones may represent a negative overall state of a server, green color tones may represent a positive overall state of a server, etc.) and (ii) one or more useful insights with respect to, at least, a carbon footprint of an entity (e.g., a server, an IHS, etc.) may be displayed in a separate window(s) to assist a related user while interpreting the insights (e.g., to help the user with respect to understanding the benefits and trade-offs of selecting different server options to execute a workload).

FIG. 2.1 shows a flowchart of a method for managing the lifecycle of a workload in accordance with one or more embodiments of the invention. The method shown in FIG. 2.1 may be performed by, for example, a workload orchestration system (103, FIG. 1.2). Other components of the system illustrated in FIGS. 1.1-1.2 may perform the method of FIG. 2.1 without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

Turning to FIG. 2.1, in step 200, a workload execution request is received. The workload execution request may be obtained from a user of a client (110A, 110N, FIG. 1.1) or from an AI agent of the AI agents (109, FIG. 1.1) discussed throughout the present disclosure. The workload execution request may be provided to the WIE (104, FIG. 1.2) for workload instantiation. The workload execution request may specify information related to the workload. For example, the information associated with the workload may include a workload type, a requested priority of the workload, requested conditions for the workload (e.g., a minimum or maximum amount of computing components, a maximum carbon emission used to execute the workload, a maximum timeframe for completing the workload, etc.). Other information may be specified in the workload execution request without departing from the invention.

As used herein, the term “computing component” refers to any hardware or logical component of an IHS with the capability for servicing at least a portion of a workload. Examples of computing components discussed throughout the present disclosure include, but are not limited to: IT assets such as servers, storage systems, and networking systems, peripherals such as racks, rack-mounted PDUs, and backup power supplies, and clients.

In step 202, a DT creation template associated with the workload is obtained based on the information. In one or more embodiments, the WIE obtains the DT creation template (e.g., 171A, FIG. 1.4) from the DT creation and storage module (102, FIG. 1.1). The obtained DT creation template may be used to initialize a workload DT in step 204.

In step 204, the workload digital twin is generated using the digital twin creation template. In one or more embodiments, the workload digital twin is generated by initializing the definitions (172, FIG. 1.4), configurations (173, FIG. 1.4), static attributes (174, FIG. 1.4), dynamic attributes (175, FIG. 1.4), methods (176, FIG. 1.4), and previous performance models (177, FIG. 1.4) based on the information obtained from the workload execution request.

In step 206, a workload scheduling of the workload is performed based on system availability, policy information, external environment information, IHS information, and workload performance models of the workload digital twin. In one or more embodiments, the workload scheduling may be performed using a workload scheduler (105, FIG. 1.2) of the workload orchestration system. The workload scheduler may obtain the generated (or otherwise initialized) workload digital twin and coordinate with a hardware management system (140, FIG. 1.2) to identify the available computing resources of the corresponding IHS. The identified available computing resources may be used to assign one or more computing resources (e.g., servers, network systems, storage systems, etc.) to execute the workload. Additionally, the workload scheduler may consult a policy engine (132, FIG. 1.2) to determine one or more policies of the IHS for workload execution, priority assignment, and/or other decisions for the workload without departing from the invention.

In step 208, the lifecycle of the workload is managed by monitoring performance, tracking energy and power grid usage, and synchronizing with the active workload digital twin. The management of the lifecycle of the workload may be managed in accordance with the method of FIG. 2.2. Other methods may be used to perform the management of the lifecycle of the workload without departing from the invention. During the lifecycle of the workload, the workload digital twin may be considered active.

In step 210, after completion of the workload, a digital twin snapshot of the workload digital twin is stored in a digital twin creation and storage module. After completion of the workload, the information generated and stored for the workload digital twin is stored as a snapshot of the digital twin.

In one or more embodiments, the active workload digital twin is re-assigned as a closed digital twin. A closed digital twin may refer to a digital twin for an entity (e.g., workload, server, IT asset, IHS, etc.) that is no longer active. The status of a digital twin may be reassigned to active at a later point in time based on the change in status of the corresponding entity. In this manner, if the workload is re-assigned as active at a later point in time, any information such as dynamic attributes, performance models, configurations, modified during the active digital twin after the re-assigning may be stored in a second snapshot of the digital twin.

In step 212, after generation of the workload digital twin, a workload report is provided to the digital twin creation and storage module using information from the workload digital twin. In one or more embodiments, the workload report is populated with relevant information associated with the workload digital twin that may be used for evaluation of workload executions of future workloads (e.g., workloads of identical types, workloads of identical configurations, and/or workloads of similar or identical computing resources used). In one or more embodiments, the workload report is the workload digital twin snapshot, and any information included in the workload report includes the information stored in the workload digital twin snapshot.

In one or more embodiments, the workload report may specify computing resource utilization such as time series of the computing resources (e.g., processing, storage, memory, etc.) used to execute the workloads. The workload report may further specify grid emission information such as a profile of the power grid used to power each computing component, a measurement of the grid emission intensity for the power grid when powering the set of computing components during execution of the workload. The workload report may further specify an energy cost of the workload. The energy cost may specify the total amount of energy consumed to power the computing components during execution of the workload. The aforementioned information may be information further stored in the digital twin (as discussed in FIG. 2.2).

In one or more embodiments, the workload scheduler includes functionality for continuous updating of the workload queue based on analysis of changes to the policy engine, system availability determined using the hardware management system, power consumption of the corresponding IHS, and/or any other information without departing from the invention. In this manner, the workload queue is consistent with the changes to the IHS including changes to the availability of the computing resources and changes to policies or priorities managed by the policy engine.

In one or more embodiments, the workload digital twin may be used for future evaluations of workloads, servers, IHSs, IT-assets, peripherals, or other computing components. For example, the workload digital twin may be used to populate an IHS digital twin to track the impact of executing the workload (and other workloads) executing in the IHS.

FIG. 2.2 shows a flowchart of a method for managing a workload in accordance with one or more embodiments of the invention. The method shown in FIG. 2.2 may be performed by, for example, a workload orchestration system (103, FIG. 1.2). Other components of the system illustrated in FIGS. 1.1-1.2 may perform the method of FIG. 2.2 without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

In step 220, the workload lifecycle manager monitors the execution of the workload. In one or more embodiments, the monitoring includes tracking energy consumption, computing resource usage of the computing components executing the workload, and carbon emission of the power grid based on the energy consumption of the computing resources and the profile of the power grid (e.g., a power source type).

In step 222, performance metrics of the workload are obtained. In one or more embodiments, the performance metrics include one or more time series of the processing, memory usage, energy consumption, storage, and/or other resources consumed to execute the workload. In one or more embodiments, the workload lifecycle manager may update the computing components executing the workload, such as removing, adding, or otherwise replacing one of the computing components originally executing the workload. The performance metrics of the updated computing components may be subsequently tracked.

In step 224, the corresponding active workload digital twin is updated based on the performance metrics. In one or more embodiments, based on the changes to the workload and based on the performance metrics, the digital twin of the workload is updated. In one or more embodiments, the updating of the digital twin includes generating (or updating) one or more performance models of the digital twin, updating the methods of the workload based on methods or tasks performed for the execution of the workload, and maintaining synchronized attributes (static or dynamic) of the workload digital twin compared to the executed workload.

In step 226, a determination is made about whether the workload is complete. If the workload is complete, the method ends following step 226; otherwise, the method proceeds to step 220.

FIG. 3.1 shows a flowchart of a method for a second life evaluation of hardware during operation in accordance with one or more embodiments of the invention. The method shown in FIG. 3.1 may be performed by, for example, a second life evaluation service (190, FIG. 1.1). Other components of the system illustrated in FIG. 1.1 may perform the method of FIG. 3.1 without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

In step 300, a hardware forecasting analysis is performed on hardware in an IHS during workload execution to obtain hardware performance metrics. In one or more embodiments, the hardware forecasting analysis includes analyzing telemetry data obtained for one or more computing components during their respective operations (e.g., while executing one or more workloads). The telemetry data may specify, for example, real-time computing resource utilization and grid emission information. The telemetry data may be associated with hardware components of the computing components. The obtained telemetry data, each corresponding to the hardware components, may be referred to as hardware performance metrics.

The hardware forecasting analysis may be initiated in step 300 based on a periodic scheduling of the hardware in the IHS. Alternatively, the hardware forecasting analysis may be initiated following completion of a workload (e.g., in accordance with the method of FIG. 2.1). For example, the hardware forecasting analysis may be performed in response to detection that a workload was completed. In another embodiment, the hardware forecasting is initiated in response to a request obtained from an external entity (e.g., an IHS) for evaluating the hardware in the IHS issuing the request or hardware of a second IHS.

In one or more embodiments, the hardware forecasting analysis includes obtaining time series information about the computing resources (e.g., processing resources, storage/memory resources, networking resources, etc.) of the hardware component over a predefined period of time, obtaining grid emission intensity information during the pre-defined period of time, and obtaining information about the workloads executing in the hardware component during the predefined period of time to store the hardware performance metrics. Other information may be tracked in the hardware performance metrics.

In another embodiment, the hardware forecasting analysis is performed in response to a decommissioning performed on hardware of the IHS. Such embodiment may be described using the method of FIG. 3.2.

Returning to FIG. 3.1, in step 302, a determination is made about whether the hardware forecasting analysis indicates a second life evaluation for a hardware component. In one or more embodiments, the determination is made based on whether the hardware performance metrics indicate an underperformance of the hardware. For example, the hardware performance metrics may be compared to historical performance models stored in one or more digital twins, and if the hardware performance metrics underperform compared to hardware metrics of the historical performance models by a predefined threshold, the determination may be made that the hardware performance metrics indicate a second life evaluation. If the hardware forecasting analysis indicates a second life evaluation, the method proceeds to step 324; otherwise, the method proceeds to step 330.

In step 304, a hardware evaluation is performed on identified hardware components to identify hardware comparisons. In one or more embodiments, the hardware evaluation includes performing testing operations on identified hardware components and compare the performance of the identified hardware components to expected performance.

In one or more embodiments, the expected performance of the hardware components may be determined using digital twins (e.g., 168A, 168N, 150A, 155A, 156A, 157A, 158A, 151A, 152A, 153A, FIG. 1.3) of the corresponding hardware component(s). Identical testing operations may be performed on the digital twins to obtain the expected performance. Alternatively, the expected performance may be extrapolated from the corresponding performance models stored in the digital twins. A hardware comparison may be performed using the expected performance and the performance of the identified hardware components.

For example, consider a scenario in which a hardware component of an IHS being evaluated is a network system (e.g., 115A, FIG. 1.2) such as a network interface card (NIC). A digital twin of the NIC may be stored in the digital twin and storage module. The second life evaluation service may obtain the digital twin of the NIC from the digital twin and storage module. A performance model of the network bandwidth and power consumption of the hardware in the NIC may be stored in the NIC digital twin. The performance model may be used to compare the hardware metrics (e.g., network bandwidth performance and power consumption) of the NIC as the NIC executes workloads and/or other operations.

In one or more embodiments, based on the hardware comparisons, the hardware evaluations may result in an indication about whether the hardware component is suited to continue to operate in the IHS.

In step 306, a residual value evaluation is performed for each hardware component to determine a repurposing of the identified hardware. In one or more embodiments, based on the hardware comparisons, a repurposing is identified for the hardware in the hardware component. Examples of repurposing for a hardware component include, but are not limited to: disassembling the hardware component and recommending resale of a portion of the hardware in the hardware component, recommending resale of the hardware component, replacing a portion of the hardware in the hardware component, replacing a portion of a different hardware component with a portion of the hardware component being repurposed, and redeploying the hardware component in a secondary computing environment.

In step 308, a repurposing of the hardware component(s) is implemented. Based on the determined repurposing of each hardware component evaluated using steps 304 and 306, the second life evaluation service may perform the repurposing of each hardware component to obtain repurposed hardware.

In step 310, following the determination that the hardware forecasting analysis does not indicate a second life evaluation, the hardware continues to be used in the current IHS.

FIG. 3.2 shows a flowchart of a method for a second life evaluation of decommissioned hardware in accordance with one or more embodiments of the invention. The method shown in FIG. 3.1 may be performed by, for example, a second life evaluation service (190, FIG. 1.1). Other components of the system illustrated in FIG. 1.1 may perform the method of FIG. 3.1 without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

In step 320, a hardware decommissioning of a hardware component in an IHS is initiated for a second life evaluation. In one or more embodiments, the hardware decommissioning is performed for the purpose of performing a hardware evaluation to determine a second life of the hardware component. The decommissioning may be initiated by any entity of the IHS, or any entity of the system (100, FIG. 1.1) discussed throughout the present disclosure.

In step 322, at least one digital twin corresponding to the decommissioned hardware is obtained from the digital twin creation and storage module. In one or more embodiments, the digital twin(s) to be obtained may be determined based on the corresponding sub-components of the hardware component. For example, consider the scenario in which the hardware component is an IT-asset that includes a server, a rack-mounted PDU, and a storage system. In such embodiment, the digital twins corresponding to each of the IT-asset, the storage system, the rack-mounted PDU, and the server are obtained for evaluation.

In step 324, a hardware evaluation is performed on the decommissioned hardware component using the at least one digital twin to identify hardware comparisons. In one or more embodiments, the hardware evaluation includes performing testing operations on the hardware component (and any sub-components) and compare the performance of the identified hardware components to expected performance.

In one or more embodiments, the expected performance of the hardware components may be determined using digital twins (e.g., 168A, 168N, 150A, 155A, 156A, 157A, 158A, 151A, 152A, 153A, FIG. 1.3) of the corresponding hardware component(s). Identical testing operations may be performed on the digital twins to obtain the expected performance. Alternatively, the expected performance may be extrapolated from the corresponding performance models stored in the digital twins. A hardware comparison may be performed using the expected performance and the performance of the identified hardware components.

For example, consider a scenario in which a hardware component of an IHS being evaluated is a network system (e.g., 115A, FIG. 1.2) such as a network interface card (NIC). A digital twin of the NIC may be stored in the digital twin and storage module. The second life evaluation service may obtain the digital twin of the NIC from the digital twin and storage module. A performance model of the network bandwidth and power consumption of the hardware in the NIC may be stored in the NIC digital twin. The performance model may be used to compare the hardware metrics (e.g., network bandwidth performance and power consumption) of the NIC as the NIC executes workloads and/or other operations.

In one or more embodiments, based on the hardware comparisons, the hardware evaluations may result in an indication about whether the hardware component is suited to continue to operate in the computing environment.

In step 326, a residual value evaluation is performed of the hardware component using the hardware comparisons and using external information from, for example, AI agents, secondary IHSs, and external services to determine a repurposing of the hardware component.

In step 328, a repurposing of the hardware components is implemented.

FIG. 4 shows a flowchart of a method for managing a digital twin in accordance with one or more embodiments of the invention. The method shown in FIG. 4 may be performed by, for example, a digital twin creation and storage module (102, FIG. 1.1). Other components of the system illustrated in FIG. 1.1 or 1.3 may perform the method of FIG. 4 without departing from the invention. While the various steps in the flowchart are presented and described sequentially, one of ordinary skill in the relevant art will appreciate that some or all of the steps may be executed in different orders, may be combined or omitted, and some or all steps may be executed in parallel.

Turning to FIG. 4, in step 400, definitions, system configurations, performance models, and attributes associated with an IHS is used to generate an IHS digital twin. In one or more embodiments, the digital twin is generated by obtaining the specified definition, system configurations, and additional information used to define the IHS. For example, the digital twin creation and storage module obtains information associated with the IHS such as the computing components (e.g., the servers, networking systems, storage systems, IT-assets, peripherals, PDUs, etc.) operating on the IHS, obtaining any relevant digital twins (if available) corresponding to the associated computing components, and information associated with the workloads executing on the IHS. Based on the aforementioned information, the definitions, configurations, attributes, performance models, and methods are initialized to generate a snapshot of the IHS digital twin.

In step 402, performance and behavioral modeling of the IHS digital twin is performed using machine learning and execution of one or more workload digital twins in the IHS digital twin to obtain performance metrics. In one or more embodiments, the performance and behavioral modeling is performed by implementing a workload digital twin in the IHS and using the generated digital twin as a simulation to generate the performance metrics. For example, for a workload that includes using a GPU, the workload may be performed using a digital twin of the GPU that simulates the behavior of the GPU to perform operations used by the workload. As a second example, for a workload that evaluates the operation of a data center that includes a large number (e.g., more than one thousand) of computing components, a digital twin of the data center may be generated and stored in the digital twin service. The performance and behavioral modeling may include modeling each computing component and performing the evaluation on simulations of the computing components in the data center to obtain evaluation metrics.

In step 404, the performance metrics are stored with the definitions, configurations, and additional information as a digital twin snapshot. In one or more embodiments, the digital twin snapshot may be stored as an active DT in the IHS (or a second IHS different from the IHS of which the digital twin is generated). A hardware management system of the IHS obtaining the digital twin may utilize the IHS digital twin for current workloads and/or other operations.

In step 406, one or more digital twins are updated based on the performance metrics and based on any generated performance models from the performance and behavioral modeling. In one or more embodiments, the digital twins of the corresponding computing components in the IHS are updated by synchronizing each IT-asset digital twin, peripheral digital twin, and workload digital twin associated with the IHS digital twin with the updated performance models, attributes, definitions, methods, and configurations. In this manner, each digital twin corresponding to the IHS digital twin is managed based on the performance and behavioral modeling of the IHS digital twin.

While the method of FIG. 4 shows one instance of the performance and behavioral modeling performed for the digital twin to generate a digital twin snapshots, any number of performance and behavioral modeling may be performed to each generate a digital twin snapshot. For example, a performance and behavioral modeling of one digital twin snapshot may be used to generate or update a second digital snapshot of the same digital twin. In this manner, each digital snapshot is preserved in an immutable ledger (internal or external to the digital twin creation and generation module), and additional digital twin snapshots are generated for each performance and behavioral modeling without requiring the modification of previous digital twin snapshots.

As discussed above, embodiments of the invention may be implemented using computing devices. FIG. 5 shows a diagram of a computing device in accordance with one or more embodiments of the invention. The computing device (500) may include one or more computer processors (502), non-persistent storage (504) (e.g., volatile memory, such as random access memory (RAM), cache memory), persistent storage (506) (e.g., a hard disk, an optical drive such as a compact disk (CD) drive or digital versatile disk (DVD) drive, a flash memory, etc.), a communication interface (512) (e.g., Bluetooth interface, infrared interface, network interface, optical interface, etc.), input devices (510), output devices (508), and numerous other elements (not shown) and functionalities. Each of these components is described below.

In one embodiment of the invention, the computer processor(s) (502) may be an integrated circuit for processing instructions. For example, the computer processor(s) may be one or more cores or micro-cores of a processor. The computing device (500) may also include one or more input devices (510), such as a touchscreen, keyboard, mouse, microphone, touchpad, electronic pen, or any other type of input device. Further, the communication interface (512) may include an integrated circuit for connecting the computing device (500) (also referred to as a “computer”) to a network (not shown) (e.g., a local area network (LAN), a wide area network (WAN) such as the Internet, mobile network, or any other type of network) and/or to another device, such as another computing device.

In one embodiment of the invention, the computing device (500) may include one or more output devices (508), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (502), non-persistent storage (504), and persistent storage (506). Many different types of computing devices exist, and the aforementioned input and output device(s) may take other forms.

One or more embodiments of the invention may be implemented using instructions executed by one or more processors of the data management device. Further, such instructions may correspond to computer readable instructions that are stored on one or more non-transitory computer readable mediums.

One or more embodiments of the invention may improve the operation of one or more computing devices. More specifically, embodiments of the invention improve the management of computing environments by providing a comprehensive view of the power usage and environmental impact at a workload-specific level. This may enable administrators of the IHSs (e.g., data centers) to optimize power usage based on management of power consumption for future workloads. For example, the power management of a computing environment that consumes a high amount of power may be modified to increase the use of environmentally friendly power sources. Additionally, the storage of such workload characterization entries may be used for data analytics such as trend identification and/or machine learning models.

Embodiments of the invention may improve the efficiency of managing computing environments that include one or more IHSs. Specifically, embodiments of the invention improve the process of evaluating hardware, software, and/or processes operating in one or more IHSs by using standardized digital twins stored in an external digital twin creation and storage module. The snapshots digital twins may be updated and managed based on performance and behavioral modeling to execute workloads, evaluate hardware, and/or otherwise improve the understanding of the operations of computing resources and their power consumption and, as such, monitoring their grid emission and carbon footprint to enable administrators or owners of the computing resources to use such monitored data to, for example, improve the operations of the computing resources while considering the environmental impact.

Further, by monitoring the hardware components for repurposing and second life evaluations, embodiments of the invention improve the use of hardware components in the computing environments by assigning the operations of the hardware components to maximize the efficient use of the hardware.

Thus, embodiments of the invention may address the problem of inefficient use of computing resources. This problem arises due to the technological nature of the environment in which computing products are developed.

The problems discussed above should be understood as being examples of problems solved by embodiments of the invention disclosed herein and the invention should not be limited to solving the same/similar problems. The disclosed invention is broadly applicable to address a range of problems beyond those discussed herein.

While the invention has been described above with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A method for managing an information handling system (IHS), the method comprising:
initiating, by a workload orchestration system, execution of a workload in the IHS,
wherein the workload is executed using a set of computing components of the IHS, and
wherein the workload is initiated based on user prioritization requirements for the set of computing components and based on a workload scheduling of the workload;
after initiating the workload, monitoring each computing component of the set of computing components executing the workload to obtain computing component information of each computing component in the set of computing components, computing resource utilization of the set of computing components, and grid emission information;
storing, in a digital twin creation tool, a digital twin of the workload based on the computing component information, the computing resource utilization, and the grid emission information; and
using the workload digital twin for evaluation of the workload after completion of the workload.

2. The method of claim 1, further comprising:
prior to initiating the execution of the workload:
obtaining a workload execution request for executing the workload,
wherein the workload execution request comprises information about the workload;
obtaining, based on the information about the workload, a digital twin creation template from the digital twin creation and storage module; and
generating the digital twin of the workload using the digital twin creation template,
wherein the digital twin of the workload is updated based on the execution of the workload.

3. The method of claim 2, wherein the workload execution request is obtained from an artificial intelligence (AI) agent.

4. The method of claim 1, wherein the digital twin of the workload comprises: definitions of the workload, configurations of the set of computing components, static attributes of the workload, dynamic attributes of the workload, and a performance model.

5. The method of claim 1, wherein the evaluation comprises:
performing a simulation of a second workload on the IHS using the digital twin; and
storing results of the simulation in a second digital twin snapshot of the digital twin.

6. The method of claim 1, wherein the computing component information comprises an identifier of each computing component of the set of computing components and a type of device for each computing component of the set of computing components.

7. The method of claim 1, wherein the computing resource utilization comprises: a first time series for memory usage of each computing component of the set of computing components for executing the workload, a second time series of persistent storage used by each computing component of the set of computing components for executing the workload, a third time series of processing used by each computing component of the set of computing components for executing the workload, and a timeframe of the workload.

8. The method of claim 1, wherein the grid emission information comprises: a profile of a power grid used to power each computing component of the set of computing components during execution of the workload and a measurement of grid emission intensity during execution of the workload.

9. The method of claim 8, wherein the measurement of grid emission intensity is used to calculate an energy cost of the workload, and wherein the energy cost is stored in the digital twin of the workload.

10. A non-transitory computer readable medium comprising computer readable program code, which when executed by a computer processor enables the computer processor to perform a method for managing an information handling system (IHS), the method comprising:
initiating, by a workload orchestration system, execution of a workload in the IHS,
wherein the workload is executed using a set of computing components of the IHS, and
wherein the workload is initiated based on user prioritization requirements for the set of computing components and based on a workload scheduling of the workload;
after initiating the workload, monitoring each computing component of the set of computing components executing the workload to obtain computing component information of each computing component in the set of computing components, computing resource utilization of the set of computing components, and grid emission information;
storing, in a digital twin creation tool, a digital twin of the workload based on the computing component information, the computing resource utilization, and grid emission information; and
using the workload digital twin for evaluation of the workload after completion of the workload.

11. The non-transitory computer readable medium of claim 10, further comprising:
prior to initiating the execution of the workload:
obtaining a workload execution request for executing the workload,
wherein the workload execution request comprises information about the workload;
obtaining, based on the information about the workload, a digital twin creation template from the digital twin creation and storage module; and
generating the digital twin of the workload using the digital twin creation template,
wherein the digital twin of the workload is updated based on the execution of the workload.

12. The non-transitory computer readable medium of claim 11, wherein the workload execution request is obtained from an artificial intelligence (AI) agent.

13. The non-transitory computer readable medium of claim 10, wherein the digital twin of the workload comprises: definitions of the workload, configurations of the set of computing components, static attributes of the workload, dynamic attributes of the workload, and a performance model.

14. The non-transitory computer readable medium of claim 11, wherein the evaluation comprises:
performing a simulation of a second workload on the IHS using the digital twin; and
storing results of the simulation in a second digital twin snapshot of the digital twin.

15. The non-transitory computer readable medium of claim 10, wherein the computing component information comprises an identifier of each computing component of the set of computing components and a type of device for each computing component of the set of computing components.

16. The non-transitory computer readable medium of claim 10, wherein the computing resource utilization comprises: a first time series for memory usage of each computing component of the set of computing components for executing the workload, a second time series of persistent storage used by each computing component of the set of computing components for executing the workload, a third time series of processing used by each computing component of the set of computing components for executing the workload, and a timeframe of the workload.

17. The non-transitory computer readable medium of claim 10, wherein the grid emission information comprises: a profile of a power grid used to power each computing component of the set of computing components during execution of the workload and a measurement of grid emission intensity during execution of the workload.

18. The non-transitory computer readable medium of claim 17, wherein the measurement of grid emission intensity is used to calculate an energy cost of the workload, and wherein the energy cost is stored in the digital twin of the workload.

19. A system, comprising:
an information handling system (IHS) comprising a workload orchestration system and a set of computing components, wherein the workload orchestration system comprises a processor; and
memory comprising instructions, which when executed by the processor, perform a method comprising:
initiating, by a workload orchestration system, execution of a workload in the IHS,
wherein the workload is executed using a set of computing components of the IHS, and
wherein the workload is initiated based on user prioritization requirements for the set of computing components and based on a workload scheduling of the workload;
after initiating the workload, monitoring each computing component of the set of computing components executing the workload to obtain computing component information of each computing component in the set of computing components, computing resource utilization of the set of computing components, and grid emission information;
storing, in a digital twin creation tool, a digital twin of the workload based on the computing component information, the computing resource utilization, and the grid emission information; and
using the workload digital twin for evaluation of the workload after completion of the workload.

20. The system of claim 19,
wherein the computing component information comprises an identifier of each computing component of the set of computing components and a type of device for each computing component of the set of computing components,
wherein the computing resource utilization comprises: a first time series for memory usage of each computing component of the set of computing components for executing the workload, a second time series of persistent storage used by each computing component of the set of computing components for executing the workload, a third time series of processing used by each computing component of the set of computing components for executing the workload, and a timeframe of the workload,
wherein the grid emission information comprises: a profile of a power grid used to power each computing component of the set of computing components during execution of the workload and a measurement of grid emission intensity during execution of the workload,
wherein the measurement of grid emission intensity is used to calculate an energy cost of the workload, and
wherein the energy cost is stored in the digital twin of the workload.
